(19) United States
(12) Patent Application Publication
(10) Pub. No.: US 2025/0216459 A1
(43) Pub. Date: Jul. 3, 2025

(54) ANOMALY DETECTION DEVICE, MECHANICAL SYSTEM, AND ANOMALY DETECTION METHOD

(71) Applicant: Mitsubishi Electric Corporation, Tokyo (JP)

(72) Inventors: Naoto TAKANO, Tokyo (JP); Yoichi HORISAWA, Tokyo (JP)

(73) Assignee: Mitsubishi Electric Corporation, Tokyo (JP)

(21) Appl. No.: 18/850,554

(22) PCT Filed: Mar. 29, 2022
(86) PCT No.: PCT/JP2022/015595

§ 371 Date: Sep. 24, 2024

(51) Int. Cl. G01R 31/34; G06N 20/00

(52) U.S. Cl. CPC G01R 31/343; G06N 20/00

(57) ABSTRACT

A state signal generation unit that detects the state of a mechanical apparatus as a state signal, a condition signal generation unit that generates a condition signal by detecting the operating status of the mechanical apparatus as an operating condition, a state feature generation unit that generates state features from the state signal, a condition feature generation unit that generates condition features from the condition signal, an initial state learning unit that executes learning based on initial learning state features and outputs initial state learning results, an initial condition learning unit that executes learning based on initial learning condition features and outputs initial condition learning results, an anomaly degree calculation unit that calculates the degree of anomaly based on state learning results and detection state features, and an unknownness degree calculation unit that calculates the degree of unknownness based on condition learning results and detection condition features are included.

### FIELD

The present disclosure relates to detection of anomalies in mechanical apparatuses.

### BACKGROUND

Anomaly detection in which sensors are installed in a mechanical apparatus, and signals from the installed sensors are analyzed so that failure, deterioration, and the like occurring in production equipment are detected is an important technology for enabling efficient operation of the mechanical apparatus. When an anomaly occurs in the mechanical apparatus due to aging deterioration of a component of the mechanical apparatus, a disturbance, or the like, the anomaly detection allows the detection of the anomaly to take measures such as the changing of an operating condition of the mechanical apparatus or the stopping and repairing of the mechanical apparatus. Examples of the component of the mechanical apparatus include a ball screw, a speed reducer, a bearing, and a pump. Examples of the anomaly occurring in the mechanical apparatus include an increase in friction, occurrence of vibration, and breakage of a casing.

As an example of the technology to detect anomalies, there is a technology called anomaly detection, outlier detection, or the like. In this anomaly detection technology, machine learning to learn the characteristics of a sensor signal in a normal state is executed to generate a model. Then, the generated model is used to quantitatively evaluate how much the sensor signal obtained in a monitored time period in which to detect anomalies deviates from the sensor signal in the normal state, to detect anomalies.

This anomaly detection technology has an advantage that occurrence of anomalies can be detected even when the sensor signal at the time of occurrence of anomalies has not been obtained in advance. On the other hand, when an operating condition of the mechanical apparatus at the time of obtaining the sensor signal to be used in learning is different from the operating condition in the monitored time period, this technology has a problem that false detection occurs due to the difference in the operating condition. Patent Literature 1 discloses a technique of calculating the degree of anomaly by machine learning and further adjusting a threshold for the degree of anomaly used in determining whether the state is normal or anomalous using load data indicating load conditions of a mechanical apparatus. The technique described in Patent Literature 1 aims to improve failure prediction accuracy when environmental conditions, load conditions, or the like have changed.

A control device described in Patent Literature 1 obtains measured values related to the state of mechanical equipment and load conditions of the mechanical equipment when the mechanical equipment is in a normal state, and generates a trained model by machine learning using the measured values as training data. Further, the control device described in Patent Literature 1 obtains measured values related to the state of the mechanical equipment from when the mechanical equipment is in a normal state until the mechanical equipment goes into an anomalous state, and obtains a first threshold using the obtained measured values and the generated trained model.

Then, the control device described in Patent Literature 1 obtains measured values related to the state of the mechanical equipment and the load conditions of the mechanical equipment at the time of evaluation. Then, the control device described in Patent Literature 1 obtains a second threshold based on the obtained load conditions at the time of the evaluation, the load conditions at the time of the generation of the trained model, and the first threshold. Then, the control device described in Patent Literature 1 determines the state of the mechanical equipment at the time of the evaluation, based on the trained model, the measured values related to the state of the mechanical equipment at the time of the evaluation, and the second threshold.

Thus, the control device of Patent Literature 1 corrects the first threshold to the second threshold, based on the differences between the load conditions at the time of the generation of the learning model and those at the time of the evaluation, and reflects, in the second threshold, changes in the mechanical equipment between the time of the generation of the learning model and the time of the evaluation, to prevent the occurrence of false detection.

In the control device described in Patent Literature 1, the second threshold cannot be accurately calculated, and the determination result will be inaccurate. In particular, when a change in state between the time of the generation of the learning model and the time of the determination does not appear in the differences in the load conditions, for example, the result of the determination will be inaccurate.

As described above, the control device of Patent Literature 1 has the problem that anomaly detection with little false detection cannot be performed when the state of the mechanical apparatus with variable operating conditions is detected.

### CITATION LIST

### Patent Literature

Patent Literature 1: Japanese Patent Application Laid-open No. 2021-086220

### SUMMARY OF INVENTION

### Problem to be Solved by the Invention

As described above, there is a problem that when the state of a mechanical apparatus with variable operating conditions is detected, anomaly detection cannot be performed with little output of erroneous determination results such as false detection and overlooking.

### Means to Solve the Problem

An anomaly detection device according to the present disclosure includes: a state signal generation unit to generate a state signal by detecting, in time series, a state of a mechanical apparatus; a condition signal generation unit to generate a condition signal by detecting, in time series, an operating condition indicating an operating status of the mechanical apparatus; a state feature generation unit to generate state features based on the state signal; a condition feature generation unit to generate condition features based on the condition signal; an initial state learning unit to output, as initial state learning results, results of learning based on initial learning state features that are the state features at a time of initial state learning; an initial condition learning unit to output, as initial condition learning results, results of learning based on initial learning condition features that are the condition features at a time of initial condition learning; an anomaly degree calculation unit to obtain the initial state learning results or additional state learning results as state learning results and calculate a degree of anomaly based on the state learning results and detection state features that are the state features at a time of detection; and an unknownness degree calculation unit to obtain the initial condition learning results or additional condition learning results as condition learning results and calculate a degree of unknownness based on the condition learning results and detection condition features that are the condition features at the time of the detection.

A mechanical system according to the present disclosure includes: a mechanical apparatus; a state signal generation unit to generate a state signal by detecting, in time series, a state of the mechanical apparatus; a condition signal generation unit to generate a condition signal by detecting, in time series, an operating condition indicating an operating status of the mechanical apparatus; a state feature generation unit to generate state features based on the state signal; a condition feature generation unit to generate condition features based on the condition signal; an initial state learning unit to output, as initial state learning results, results of learning based on initial learning state features that are the state features at a time of initial state learning; an initial condition learning unit to output, as initial condition learning results, results of learning based on initial learning condition features that are the condition features at a time of initial condition learning; an anomaly degree calculation unit to obtain the initial state learning results or additional state learning results as state learning results and calculate a degree of anomaly based on the state learning results and detection state features that are the state features at a time of detection; and an unknownness degree calculation unit to obtain the initial condition learning results or additional condition learning results as condition learning results and calculate a degree of unknownness based on the condition learning results and detection condition features that are the condition features at the time of the detection.

An anomaly detection method according to the present disclosure includes: a state signal generation step of generating a state signal by detecting, in time series, a state of a mechanical apparatus; a condition signal generation step of generating a condition signal by detecting, in time series, an operating condition indicating an operating status of the mechanical apparatus; a state feature generation step of generating state features based on the state signal; a condition feature generation step of generating condition features based on the condition signal; an initial state learning step of outputting, as initial state learning results, results of learning based on initial learning state features that are the state features at a time of initial state learning; an initial condition learning step of outputting, as initial condition learning results, results of learning based on initial learning condition features that are the condition features at a time of initial condition learning; an anomaly degree calculation step of obtaining the initial state learning results or additional state learning results as state learning results and calculating a degree of anomaly based on the state learning results and detection state features that are the state features at a time of detection; and an unknownness degree calculation step of obtaining the initial condition learning results or additional condition learning results as condition learning results and calculating a degree of unknownness based on the condition learning results and detection condition features that are the condition features at the time of the detection.

### Effects of the Invention

According to the present disclosure, when the state of the mechanical apparatus with variable operating conditions is detected, anomaly detection can be performed with less output of erroneous determination results such as false detection and overlooking.

### BRIEF DESCRIPTION OF DRAWINGS

FIG. 1 is a diagram illustrating an example of a configuration of a mechanical system according to a first embodiment.

FIG. 2 is a diagram illustrating configurations of a mechanical apparatus and a control device according to the first embodiment.

FIG. 3 is a diagram illustrating an exemplary configuration when a processor and a memory constitute processing circuitry included in the mechanical system according to the first embodiment.

FIG. 4 is a diagram illustrating an exemplary configuration when dedicated hardware constitutes the processing circuitry included in the mechanical system according to the first embodiment.

FIG. 5 is a diagram illustrating an example of time waveforms of motor speed and motor torque according to the first embodiment.

FIG. 6 is a diagram illustrating an example of time waveforms of motor speed and motor torque in continuous positioning according to the first embodiment.

FIG. 7 is a diagram illustrating the example of time waveforms of motor speed and motor torque in continuous positioning according to the first embodiment.

FIG. 8 is a diagram illustrating an example of an autoencoder according to the first embodiment. It is a diagram illustrating temporal changes in the degree of anomaly and a determination result in the conventional anomaly detection device in regards to the first embodiment.

FIG. 9 is a diagram illustrating an example of a configuration in which an anomaly determination unit is omitted from an anomaly detection device according to the first embodiment.

FIG. 10 is an example of temporal changes in the degree of anomaly and a determination result generated by the configuration in which the anomaly determination unit is omitted from the anomaly detection device according to the first embodiment.

FIG. 11 is an example, which is different from that in FIG. 10, of temporal changes in the degree of anomaly, the degree of unknownness, and the determination result generated by the configuration in which the anomaly determination unit is omitted from the anomaly detection device according to the first embodiment.

FIG. 12 is a diagram illustrating temporal changes in the degree of anomaly, the degree of unknownness, and a determination result generated by the anomaly detection device according to the first embodiment.

FIG. 13 is a diagram illustrating an example of an operation flow of the anomaly determination unit according to the first embodiment.

FIG. 14 is a block diagram illustrating an example of a configuration of a mechanical system according to the first embodiment.

FIG. 15 is a block diagram illustrating an example of a configuration of a mechanical system according to a second embodiment.

FIG. 16 is a block diagram illustrating an example of a configuration of an additional condition learning unit according to the second embodiment.

FIG. 17 is a block diagram illustrating an example of a configuration of an additional state learning unit according to the second embodiment.

FIG. 18 is a flowchart illustrating an example of operation of the additional condition learning unit according to the second embodiment.

FIG. 19 is a flowchart illustrating an example of operation of the additional state learning unit according to the second embodiment.

FIG. 20 is a diagram illustrating an example of temporal changes in the degree of anomaly, the degree of unknownness, and a determination result generated by a configuration in which the additional condition learning unit and the additional state learning unit are omitted from an anomaly detection device according to the second embodiment.

FIG. 21 is a diagram illustrating an example of temporal changes in the degree of anomaly, the degree of unknownness, and a determination result generated by a configuration in which the additional state learning unit is omitted from the anomaly detection device according to the second embodiment.

### DESCRIPTION OF EMBODIMENTS

Hereinafter, embodiments will be described in detail with reference to the drawings. Note that the embodiments described below are examples, and the scope of the present disclosure is not limited by the embodiments described below. The embodiments described below can be combined as appropriate to be implemented.

### First Embodiment

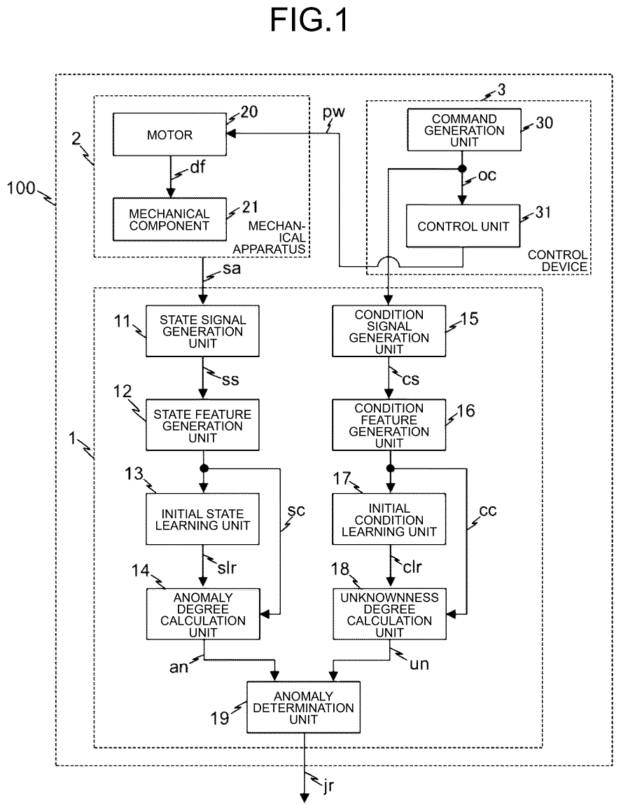

FIG. 1 is a diagram illustrating an example of a configuration of a mechanical system 100 according to the present embodiment. The mechanical system 100 includes an anomaly detection device 1 that detects anomalies occurring in a mechanical apparatus 2, the mechanical apparatus 2, and a control device 3 that controls the mechanical apparatus 2. The anomaly detection device 1 includes a state signal generation unit 11 that generates a state signal ss and a state feature generation unit 12 that generates state features sc. The anomaly detection device 1 includes an initial state learning unit 13 that executes learning based on the state features sc and outputs initial state learning results slr, and an anomaly degree calculation unit 14 that calculates the degree of anomaly an.

The anomaly detection device 1 includes a condition signal generation unit 15 that generates a condition signal cs, a condition feature generation unit 16 that generates condition features cc, and an initial condition learning unit 17 that executes learning based on the condition features cc and outputs initial condition learning results clr. The anomaly detection device 1 includes an unknownness degree calculation unit 18 that calculates the degree of unknownness un, and an anomaly determination unit 19 that determines whether the state of the mechanical apparatus 2 is anomalous or normal, based on the degree of anomaly an and the degree of unknownness un.

Here, initial state learning executed by the initial condition learning unit 17 and additional state learning described in a second embodiment are each an embodiment of state learning. A detection state signal dss, an initial learning state signal lss, and an additional learning state signal alss described in the second embodiment are each an embodiment of the state signal ss. Initial learning state features lsc and detection state features dsc are each an embodiment of the state features. The initial state learning results slr and additional state learning results aslr are each an embodiment of state learning results. The initial state learning and initial condition learning may be referred to as initial learning.

The initial condition learning and additional condition learning described in the second embodiment are each an embodiment of condition learning. A detection condition signal dcs, an initial learning condition signal lcs, and the additional learning state signal alss described in the second embodiment are each an embodiment of the condition signal cs. Initial learning condition features lcc and detection condition features dcc are each an embodiment of the condition features cc. The initial condition learning results clr and additional condition learning results aclr described in the second embodiment are an embodiment of condition learning results.

The mechanical apparatus 2 of FIG. 1 includes a motor 20 that generates a driving force df and a mechanical component 21 driven by the driving force df. The control device 3 includes a command generation unit 30 that outputs an operating condition oc, and a control unit 31 that outputs power pw to the mechanical apparatus 2, based on the operating condition oc. Examples of the mechanical apparatus 2 include an electronic component mounter, semiconductor manufacturing equipment, an industrial robot, food manufacturing equipment, a packaging machine, a conveyance apparatus, an automatic door, a press machine, a roll feeder, air-conditioning equipment, and a generator.

The operations of the mechanical apparatus 2 and the control device 3 will be illustrated. The command generation unit 30 generates the operating condition oc to be a control signal that defines the operation of the mechanical apparatus 2. The command generation unit 30 supplies the power pw to the mechanical apparatus 2, based on the operating condition oc. The motor 20 generates the driving force df for the mechanical component 21 using the power pw to drive the mechanical apparatus 2. The mechanical component 21 may be any component operated by the driving force df. Examples of the mechanical component 21 include a moving component operated by the driving force df of the motor 20, and a member connecting moving components.

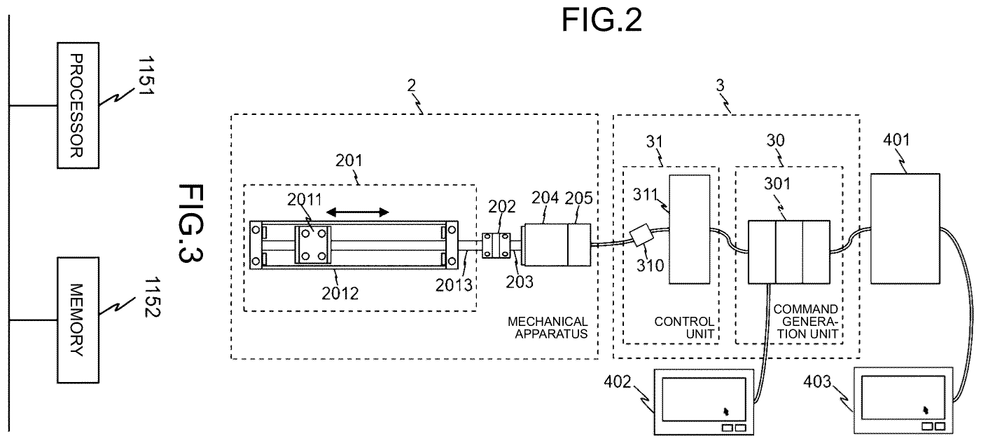

FIG. 2 is a diagram illustrating configurations of the mechanical apparatus 2 and the control device 3 according to the present embodiment. The mechanical apparatus 2 illustrated in FIG. 2 includes a ball screw 201, a coupling 202, a servomotor shaft 203, and a servomotor 204 corresponding to the motor 20 in FIG. 1. Here, the driving force df in FIG. 1 corresponds to a driving torque produced by the servomotor 204 in the example of FIG. 2. The ball screw 201 includes a moving part 2011 that moves when a ball screw shaft 2013 rotates, a guide 2012 that limits the direction of movement of the moving part 2011, and the ball screw shaft 2013.

The ball screw shaft 2013 and the servomotor shaft 203 are each mechanically connected to the coupling 202. The driving force df, which is the driving torque produced by the servomotor 204, is transmitted from the servomotor shaft 203 through the coupling 202 to the ball screw shaft 2013. The ball screw 201 translates rotational motion into linear motion by a screw mechanism, moving the moving part 2011 in two directions as indicated by arrows illustrated in FIG. 2. The guide 2012 supports the moving part 2011, limiting its movement while allowing its movement in the arrow directions, and thereby improving the accuracy of the movement of the moving part 2011. The moving part 2011 is connected to the mechanical component 21 (not illustrated), and the mechanical component 21 operates according to the purpose of the mechanical apparatus 2.

The command generation unit 30 illustrated in FIG. 2 includes a programmable logic controller (PLC) 301. The PLC 301 generates a command to move the servomotor 204 and outputs the command to a driver 311. Examples of the command include signals specifying the position, speed, torque, and the like of the servomotor 204. This command corresponds to the operating condition oc in FIG. 1. When necessary, a personal computer (PC) 401 may be further provided to the PLC 301. In the example of FIG. 2, the PC 401 outputs a command on the operation of the mechanical apparatus 2 to the PLC 301. As the PC 401, for example, a PC for industrial use (a factory automation PC or an industrial PC) may be used.

The control unit 31 includes the driver 311 and a current sensor 310. An encoder 205 that measures the rotation angle of the servomotor 204 is mounted in the mechanical apparatus 2. The current sensor 310 measures a drive current supplied from the driver 311 to the servomotor 204. The drive current corresponds to the power pw in FIG. 1.

The driver 311 performs feedback control of the servomotor 204 based on the measured value of the current sensor 310 and the measured value of the encoder 205, and supplies a drive current to the servomotor 204. In other words, the driver 311 performs feedback control to cause the operation of the servomotor 204 to follow the command generated by the PLC 301. As described above, the command generated by the PLC 301 corresponds to the operating condition oc in FIG. 1.

In the examples of FIGS. 1 and 2, the state signal ss used to detect the state of the mechanical apparatus 2 is a motor torque mt. The state signal ss of the present embodiment is not limited to this example. The state signal ss may be any signal including information on the state of the mechanical apparatus 2. Examples of the state signal ss include signals of physical quantities measured by sensors provided in the mechanical apparatus 2 or sensors provided around the mechanical apparatus 2, such as the position, speed, acceleration, current, voltage, torque, force, pressure, sound, and light amount. The state signal ss may be an image information signal.

In the example of FIG. 2, the encoder 205 and the current sensor 310 are illustrated as examples of sensors used to obtain a state quantity sa, but the sensors used to obtain the state quantity sa are not limited to them. Examples of the sensors used to obtain the state quantity sa include a laser displacement meter, an angle encoder, a gyro sensor, a vibration meter, an acceleration sensor, a voltmeter, a torque sensor, a pressure sensor, a microphone, a light sensor, and a camera. These sensors do not necessarily need to be installed near the mechanical apparatus 2, the motor 20, and the like, and may be provided at any place where the state quantity sa can be generated. For example, an acceleration sensor may be installed on the outer surface of the guide 2012, and the acceleration measured by the acceleration sensor may be output as the state signal ss. Here, the outer surface of the guide 2012 is a surface on the side opposite to the side on which the moving part 2011 is disposed.

As illustrated in FIG. 2, the command generation unit 30 may include a PLC display 402 that displays the state of the PLC 301, and a PC display 403 that displays the state of the PC 401. Note that a plurality of drive sources such as the servomotor 204 may be provided to one mechanical apparatus 2. A plurality of drivers 311 may be provided to one mechanical apparatus 2 as necessary. The single PLC 301 may centrally operate the mechanical apparatus 2, or a plurality of PLCs 301 may cooperatively operate the mechanical apparatus 2. The above is the description of the examples of the mechanical apparatus 2 and the control device 3 illustrated in FIG. 2

Note that the mechanical apparatus 2, which is an object of anomaly detection by the anomaly detection device 1, is not limited to the example illustrated in FIG. 2. The type of anomaly that is an object of anomaly detection is not limited to the example illustrated in FIG. 2. The anomaly detection device 1 can be widely applied to general phenomena occurring in the mechanical apparatus 2. Events occurring in the mechanical apparatus 2, phenomena occurring in the mechanical apparatus 2, the state of the mechanical apparatus 2, and the like can be regarded as anomalies. Examples of the phenomena that can be regarded as anomalies include the intrusion of foreign matter into the mechanical apparatus 2, the breakage of the casing of the mechanical apparatus 2, the deterioration of grease, the peeling of the material, a defect in a workpiece, a defect in fluid, a flaw in the installation of the apparatus, and a defect in assembly. A situation in which two or more phenomena have occurred may be detected as an anomaly.

FIG. 3 is a diagram illustrating an exemplary configuration when a processor 1151 and a memory 1152 constitute processing circuitry included in the mechanical system 100 according to the present embodiment. For example, processing circuitry of FIG. 3 may be included in the anomaly detection device 1 and the control device 3 illustrated in FIG. 1, the driver 311 illustrated in FIG. 2, and the like. When the processing circuitry includes the processor 1151 and the memory 1152, functions of the processing circuitry such as the anomaly detection device 1, the control device 3, and the driver 311 are implemented by software, firmware, or a combination of software and firmware. Software or firmware is described as programs and stored in the memory 1152. In the processing circuitry, the functions are implemented by the processor 1151 reading and executing the programs stored in the memory 1152. That is, when the anomaly detection device 1, the control device 3, the driver 311, and the like include the processing circuitry, the processing circuitry includes the memory 1152 for storing programs that result in the execution of processing of the anomaly detection device 1, the control device 3, the driver 311, and the like. These programs can be said to cause a computer to perform procedures and methods performed by the anomaly detection device 1, the control device 3, the driver 311, and the like.

Here, the processor 1151 may be arithmetic means called a central processing unit (CPU), a processing device, an arithmetic device, a microprocessor, a microcomputer, or a digital signal processor (DSP). The memory 1152 may be nonvolatile or volatile semiconductor memory such as RAM, read-only memory (ROM), a flash memory, an erasable programmable ROM (EPROM), or an electrically EPROM (EEPROM) (registered trademark). The memory 1152 may be storage means such as a magnetic disk, a flexible disk, an optical disk, a compact disc, a mini disc, or a digital versatile disc (DVD)

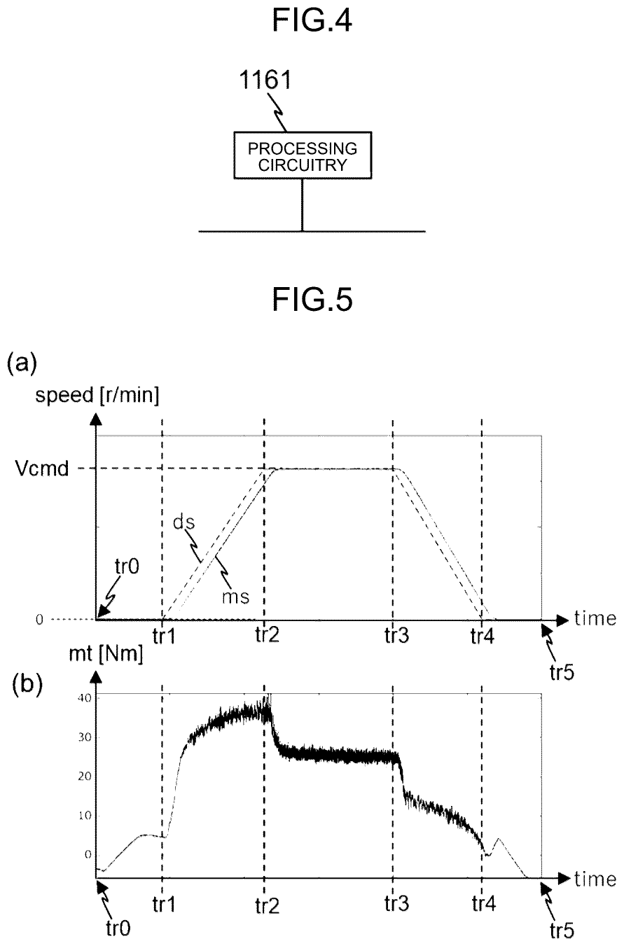

FIG. 4 is a diagram illustrating an exemplary configuration when dedicated hardware constitutes the processing circuitry included in the mechanical system 100 according to the present embodiment. For example, processing circuitry of FIG. 4 may be included in the anomaly detection device 1 and the control device 3 illustrated in FIG. 1, the driver 311 illustrated in FIG. 2, and the like. When dedicated hardware constitutes the processing circuitry, processing circuitry 1161 illustrated in FIG. 4 may be, for example, a single circuit, a combined circuit, a programmed processor, a parallel-programmed processor, an application-specific integrated circuit (ASIC), a field-programmable gate array (FPGA), or a combination of them. For the processing circuitry included in the mechanical system 100, a plurality of functions such as the anomaly detection device 1 and the control device 3 illustrated in FIG. 1 and the driver 311 may be implemented by the processing circuitry 1161 on an individual function basis, or the plurality of functions may be collectively implemented by the processing circuitry 1161. The anomaly detection device 1, the control device 3, the driver 311, the PLC 401, and the like may be connected via a network. At least one of the anomaly detection device 1, the control device 3, the driver 311, the PLC 401, and the like may be present on a cloud server.

The driver 311, the PLC 301, the PC 401, and the like may be omitted from the configuration of FIG. 2. For example, instead of the driver 311, the PLC 301, the PC 401, and the like, a device for performing anomaly detection by the anomaly detection device 1 may be separately prepared, and the device may perform the operation of the anomaly detection device 1. For example, a device including a battery, a microcomputer, a sensor, a display, and a communication function is prepared. The device obtains sound generated by the mechanical apparatus 2 as the state signal ss with a microphone. Then, the anomaly detection device 1 may detect the state of the mechanical apparatus 2 based on the state signal ss.

In the exemplary configuration of FIG. 2, the PLC display 402, the PC display 403, and the like can be omitted. In the exemplary configuration of FIG. 2, instead of these display devices, LEDs or the like provided at the driver 311 and the PLC 301 may be used to indicate the states of the servomotor 204, the ball screw 201, and the like. The results of determination as to whether the states are normal or anomalous may be indicated using the LEDs or the like. Alternatively, the states, the determination results on the states, and the like may not be indicated, and when it is determined that an anomaly has occurred, the driving of the servomotor 204 may be stopped.

In the description of FIG. 2, the speed of the servomotor 204 is obtained from the encoder 205 provided to the servomotor 204, but the present embodiment is not limited to this embodiment. For example, in the configuration of FIG. 1, the condition signal generation unit 15 may generate the motor speed as the condition signal cs, using the control signal from the command generation unit 30 that issues a drive command to the motor 20 as the operating condition oc.

Although the example in which the servomotor 204 is a rotary servomotor has been described in the example of FIG. 2, the anomaly detection device 1 of the present embodiment can be applied when the motor 20 of FIG. 1 is a motor other than the rotary type. Examples of the motor other than the rotary type include a linear servomotor, an induction motor, a stepping motor, a brush motor, and an ultrasonic motor. When a drive source different from the motor is used instead of the motor, the anomaly detection device 1 of the present embodiment can also be applied. As an example of the drive source other than the motor, for example, the mechanical apparatus 2 may be driven by an internal combustion engine such as a gasoline engine, a jet engine, a rocket engine, or a gas turbine. Thus, the drive source is not limited to one driven by electric power.

The mechanical apparatus 2 may be driven by natural energy such as wind power, geothermal power, or hydraulic power. For example, the mechanical apparatus 2 may be a wind power generator, a geothermal power generator, a hydraulic power generator, or the like. When the mechanical apparatus 2 is driven according to a command to the motor, the internal combustion engine, or the like, this command can be used as the operating condition oc. The command does not include many disturbances. Thus, by using the command as the operating condition oc, the anomaly detection device 1 can detect anomalies with high accuracy. Furthermore, the anomaly detection device 1 can detect anomalies while preventing occurrence of false detection, overlooking, and the like. When the mechanical apparatus 2 is driven by natural energy like, for example, a wind power generator, the mechanical system 100 may not include the control device 3.

Although the mechanical apparatus 2 illustrated in FIG. 1 includes the ball screw 201 and the coupling 202 as its components, the components of the mechanical apparatus 2 are not limited to them. Examples of the components of the mechanical apparatus 2 other than the ball screw 201 and the coupling 202 include a speed reducer, a guide, a belt, a screw, a pump, a bearing, and a casing. Thus, the anomaly detection device 1 can be applied to various mechanical apparatuses 2.

The operation of the anomaly detection device 1 will be illustrated. In the example of FIG. 2, an increase in vibration, an increase in friction, and the like due to the deterioration of a sliding part of the ball screw 201 are examples of anomalies detected by the anomaly detection device 1. The state signal generation unit 11 obtains the state quantity sa of a physical phenomenon that has occurred in the mechanical apparatus 2 detected using a sensor or the like, and outputs the state quantity sa as the state signal ss in time series. Here, the physical phenomenon is a quantity that can be detected on the mechanical apparatus 2, using a sensor or the like. For example, the state quantity sa may be a quantity in which the effect of failure, deterioration, or the like that has occurred in the mechanical apparatus 2 has appeared. The state quantity sa may be a quantity that allows the detection of the state of the mechanical apparatus 2, or failure, deterioration, or the like that has occurred in the mechanical apparatus 2 to be detected. The anomaly detection device 1 may be configured such that the state quantity sa is a quantity having a correlation with the state of the mechanical apparatus 2 or failure, deterioration, or the like that has occurred in the mechanical apparatus 2.

In the present embodiment, a time-series signal is a signal including information associated with each of a plurality of time points. For example, by specifying a certain time point among a plurality of time points of a time-series signal, a signal or a value indicated by a signal corresponding to that time point is determined. Such a signal may be used as a time-series signal.

Here, the state signal ss obtained when the state signal generation unit 11 detects the state of the mechanical apparatus 2 in an initial state learning time is referred to as the initial learning state signal lss. Here, the initial state learning time is desirably a time when the mechanical apparatus 2 is in a normal state. A time for anomaly detection in which the state signal generation unit 11 detects the state of the mechanical apparatus 2 is referred to as a detection time. The state signal ss detected by the state signal generation unit 11 in the detection time is referred to as the detection state signal dss. The relationship between the initial state learning time and the detection time is not limited. However, when the detection time is later than the initial state learning time, there is an advantage that the results of the initial state learning can be used for anomaly detection.

In the example of FIG. 2, the value of the driving torque calculated from the value of the current flowing through the servomotor 204, which is an example of the motor 20, is used as the state quantity sa. The state signal generation unit 11 measures the value of the drive current using the current sensor 310, converts the current value into a torque value that is the value of the driving torque produced by the servomotor 204, and uses the torque value as the state signal ss. The state quantity sa may vary from moment to moment according to the behavior of the mechanical apparatus 2, time, and the like.

The state feature generation unit 12 obtains the state signal ss in time series. Then, the state feature generation unit 12 generates the state features sc from the time-series state signal ss. The state features sc are desirably extracted features indicating the state of the mechanical apparatus 2. The state features sc may not be a time-series signal, but are desirably produced in time series. The state feature generation unit 12 may generate the state features sc one by one for each set containing a plurality of time points at which the state signal ss has been generated. Alternatively, the state feature generation unit 12 may generate the state features sc one by one for each of a plurality of time points at which the state signal ss has been generated. Here, the state features sc generated by the state feature generation unit 12 from the initial learning state signal lss are referred to as the initial learning state features lsc. The state features sc generated by the state feature generation unit 12 from the detection state signal dss are referred to as the detection state features dsc.

The initial state learning unit 13 executes learning based on the initial learning state features lsc, and outputs the results of the learning as the initial state learning results slr. The learning executed by the initial state learning unit 13 is referred to as initial state learning. For example, the initial state learning unit 13 may generate a model for the characteristics of the initial learning state signal lss, and output the structure, parameters, etc. of the model as the initial state learning results slr. Instead of the initial state learning unit 13, the anomaly detection device 1 may include a learning model on which the initial state learning has been executed, the initial state learning results slr that have been output, etc. For example, the anomaly detection device 1 may include a model based on the initial state learning results slr output by the initial state learning unit 13 described in the present embodiment. When the anomaly detection device 1 includes a trained learning model, the initial state learning results slr that have been output, etc., the anomaly detection device 1 can use the results of the initial state learning without executing the initial state learning.

The anomaly degree calculation unit 14 calculates the degree of anomaly an based on the detection state features dsc and the initial state learning results slr. The anomaly degree calculation unit 14 may calculate the degree of discrepancy between the characteristics of the detection state signal dss and the characteristics of the initial learning state signal lss as the degree of anomaly an. Alternatively, the anomaly degree calculation unit 14 may calculate the difference between the characteristics of the detection state features dsc and the characteristics of the initial learning state features lsc as the degree of anomaly an.

For example, assume that the initial state learning results slr include the model structure, the model parameters, etc. In this case, the anomaly degree calculation unit 14 generates a model from the model structure, the model parameters, etc. Then, the anomaly degree calculation unit 14 may calculate the difference between output when the initial learning state features lsc are input to the model and output when the detection state features dsc are input to the model as the degree of anomaly an.

The condition signal generation unit 15 obtains an operating condition of the mechanical apparatus 2 as the operating condition oc, and generates the condition signal cs. The operating condition oc may be any condition that indicates the operating status of the mechanical apparatus 2. In the description of FIGS. 1 and 2, the operating condition oc is a set value or a command value of the speed of the motor 20, a set value or a command value of the acceleration of the motor 20, a set value or a command value of the travel distance of the motor 20, or the like. In the description of FIGS. 1 and 2, the condition signal cs is a command speed ds that is a speed command and a time-series signal. The condition signal cs is a signal of the operating condition oc obtained in time series. Other examples of the operating condition oc and the condition signal cs include jerk, the magnitude of a load, the outside temperature, pressure, and a flow rate.

Here, the condition signal cs obtained by the condition signal generation unit 15 detecting the state of the mechanical apparatus 2 in an initial condition learning time is referred to as the initial learning condition signal lcs. Here, the initial condition learning time is desirably a time when the mechanical apparatus 2 is in a normal state. The condition signal cs detected by the condition signal generation unit 15 in the detection time, which is the time in which to detect the state of the mechanical apparatus 2, is referred to as the detection condition signal dcs.

The relationship between the initial condition learning time and the detection time is not limited. However, the detection time is preferably a time later than the initial condition learning time because the results of the initial condition learning can be used for anomaly detection. Here, the initial state learning time and the initial condition learning time do not necessarily need to coincide with each other. In contrast, the detection time in the description of the detection state signal dss coincides with the detection time in the description of the detection condition signal dcs.

The condition feature generation unit 16 generates the initial learning condition features lcc from the initial learning condition signal lcs. For example, the condition feature generation unit 16 may extract features indicating the characteristics of the operating condition oc in the initial condition learning time from the initial learning condition signal lcs, to generate the initial learning condition features lcc. The initial condition learning unit 17 executes learning based on the initial learning condition features lcc, and outputs the results of the learning as the initial condition learning results clr. The learning executed by the initial condition learning unit 17 is referred to as initial condition learning. The initial condition learning, the initial state learning, and the like may be referred to as initial learning.

For example, the initial condition learning unit 17 may model the characteristics of the operating condition oc in the initial condition learning time, based on the initial learning condition features lcc, and output the structure, parameters, etc. of the model as the initial condition learning results clr. Instead of the initial condition learning unit 17, the anomaly detection device 1 may include a trained learning model, the initial condition learning results clr that have been output, etc. When the anomaly detection device 1 includes the trained learning model, the initial condition learning results clr that have been output, etc., the anomaly detection device 1 can perform highly accurate anomaly detection in a short time, using the results of the learning without executing learning. Further, the anomaly detection device 1 can reduce the load of calculation. For example, the trained learning model may be a model based on the initial condition learning results clr output by the initial condition learning unit 17.

The unknownness degree calculation unit 18 calculates the degree of unknownness un based on the initial condition learning results clr and the detection condition signal dcs. The degree of unknownness un may be a quantity representing the degree of discrepancy between the initial learning condition signal lcs and the detection condition signal dcs. The unknownness degree calculation unit 18 may calculate the degree of discrepancy in characteristics between the detection condition features dcc and the initial learning condition features lcc as the degree of unknownness un.

For example, assume that the initial condition learning results clr include the model structure, the model parameters, etc. In this case, the unknownness degree calculation unit 18 generates a model from the model structure, the model parameters, etc. Then, the unknownness degree calculation unit 18 may calculate, as the degree of unknownness un, the difference between output when the initial learning condition features lcc are input to the model and output when the detection condition features dcc are input to the model.

The anomaly determination unit 19 determines whether or not an anomaly has occurred in the mechanical apparatus 2, based on the degree of anomaly an and the degree of unknownness un, and outputs the determination as a determination result jr. For example, when the degree of anomaly an is greater than a predetermined first threshold and the degree of unknownness un is less than a predetermined second threshold, the anomaly determination unit 19 may determine that the state of the mechanical apparatus 2 is anomalous.

In either of two cases, a case where the degree of anomaly an is less than or equal to the first threshold, and a case where the degree of unknownness un is greater than or equal to the second threshold, the anomaly determination unit 19 may determine that the state of the mechanical apparatus 2 is normal. Here, the case where the degree of anomaly an is less than or equal to the first threshold is a case where the degree of anomaly an is less than the first threshold or equal to the first threshold. The case where the degree of unknownness un is greater than or equal to the second threshold is a case where the degree of unknownness un is greater than the second threshold or equal to the second threshold.

The anomaly detection device 1 may not include the anomaly determination unit 19. In this case, a device outside the anomaly detection device 1 may perform the processing of the anomaly determination unit 19. Alternatively, an operator may perform the processing of the anomaly determination unit 19. The anomaly determination unit 19 executes machine learning using the degree of anomaly an and the degree of unknownness un as training data to generate a model. Then, the anomaly determination unit 19 may make a determination based on the generated model and the degree of anomaly an and the degree of unknownness un obtained in the detection time for the anomaly detection of the mechanical apparatus 2. The anomaly detection device 1 may include a display unit that displays the determination result jr, the degree of unknownness un, the degree of anomaly an, etc.

FIG. 5 is a diagram illustrating an example of time waveforms of motor speed ms and motor torque mt according to the present embodiment. The condition signal generation unit 15 generates the command speed ds as the condition signal cs. In FIG. 5(a), a time-series waveform of the command speed ds generated by the condition signal generation unit 15 as the condition signal cs is indicated by a dotted line, that is, a broken line. The command speed ds is the command speed ds of the motor defined by the operating condition oc generated by the command generation unit 30. In FIG. 5(a), in addition to the command speed ds, the motor speed ms calculated from the results of measurement by the encoder 205 is indicated by a solid line. FIG. 5(b) illustrates a time-series waveform of the motor torque mt generated by the state signal generation unit 11 as the state signal ss. The horizontal axes in FIGS. 5(a) and 5(b) represent time. Points denoted by reference numerals on the time axis in FIG. 5(a) and points on the time axis in FIG. 5(b) denoted by the same reference numerals as the reference numerals in FIG. 5(a) specify the same times.

Temporal changes in the command speed ds illustrated in FIG. 5(a) will be described. Between time tr0 and time tr1, the command speed ds is zero. Between time tr1 and time tr2, the command speed ds is a command to accelerate at a constant acceleration. Then, the command speed ds, which has been zero at time tr1, reaches a speed Vcmd at time tr2. Between time tr2 and time tr3, the command speed ds is maintained at the speed Vcmd. Between time tr3 and time tr4, the command speed ds is a command to decelerate at a constant acceleration. The command speed ds, which has been the speed Vcmd at time tr3, becomes zero at time tr4. Then, between time tr4 and time tr5, the command speed ds is maintained at zero.

The motor speed ms in FIG. 5(a) is actual measured values of the speed of the motor 20. In other words, the motor speed ms is actual measured values of the speed of the servomotor 204 in FIG. 2. The servomotor 204 is controlled by the command generation unit 30, that is, by the driver 311 in FIG. 2 such that the motor speed ms follows the command speed ds. The relationship between the command speed ds and the motor speed ms changes depending on the configuration of the command generation unit 30. FIG. 5(a) illustrates a case where the motor speed ms follows the command speed ds with a slight delay. In FIG. 5(b), the time-series waveform of the motor torque mt calculated from measured values of the current sensor 310 is indicated by a solid line. Assume that a signal directly obtained from the current sensor 310 is a signal obtained by measuring three-phase currents flowing in the servomotor 204 in FIG. 2 (the three-phase currents are not illustrated). The state signal generation unit 11 converts the three-phase currents to produce the motor torque mt illustrated in FIG. 5(b) as the state signal ss.

As in the example of FIG. 5, a sensor may be installed for the mechanical apparatus 2 as appropriate. The sensor may be included in the state signal generation unit 11 or may be included in the anomaly detection device 1. The state signal generation unit 11 may perform conversion on measured values of the sensor as appropriate. In addition to or instead of the sensor illustrated in the description of FIG. 5, the state signal generation unit 11 may generate the state signal ss based on the results of measurement of a sensor that detects the value of torque, force, vibration, speed, position, light amount, sound, or the like produced in the mechanical component 21. Examples of the sensor include a torque sensor, a force sensor, a vibration sensor, a gyro sensor, an encoder, a laser displacement meter, a photosensor, and a microphone. Note that the state signal generation unit 11 may generate the state signal ss directly from three-phase current values detected by the current sensor 310. Furthermore, the state signal generation unit 11 may generate the state signal ss from the rotation angle of the servomotor 204 obtained from the encoder 205, or the motor speed ms determined from the rotation angle by numerical differentiation or the like.

Time-series changes in the state signal ss will be described. The time-series waveform of the motor torque mt described with reference to FIG. 5(a) is a waveform indicating acceleration of the servomotor 204 between time tr1 and time tr2. Then, the waveform indicates deceleration of the servomotor 204 between time tr3 and time tr4. The motor torque mt illustrated in FIG. 5(b) increases between time tr1 and time tr2 accordingly. The motor torque mt illustrated in FIG. 5(b) decreases between time tr3 and time tr4.

The time waveform of FIG. 5(b) illustrates how the motor torque mt changes depending on the motor speed ms due to the action of frictional force. For example, between time tr1 and time tr2, the motor speed ms keeps accelerating at the same acceleration, but the motor torque mt increases as the motor speed ms increases.

FIGS. 5(a) and 5(b) illustrate the waveforms when a single drive called positioning is performed from a state where the servomotor 204 is stopped. In the example of FIG. 5, a case where the number of times of positioning is one has been illustrated, but positioning may be performed a plurality of times. In FIG. 5, operation when positioning of the mechanical component 21 is performed by the servomotor 204 has been described, but the application of the anomaly detection device 1 of the present embodiment is not limited to positioning operation. For example, the anomaly detection device 1 of the present embodiment can also be applied to control different from positioning operation, such as speed control and torque control. Furthermore, for example, the anomaly detection device 1 of the present embodiment can also be applied to anomaly detection of the mechanical apparatus 2 that is not controlled, following a command.

In the example of FIG. 5, a case where the command speed ds includes a time in which the command speed ds is constant has been illustrated. In other words, in the example of FIG. 5, a case where the time waveform of the command speed ds has a trapezoidal shape has been illustrated. The anomaly detection device 1 of the present embodiment is also applicable to a case where the time waveform of the command speed ds is not trapezoidal, such as a case where there is no time in which the command speed ds is constant, that is, a case where the waveform is triangular. In the example of FIG. 5, a case where the slope of the speed at the time of acceleration is constant, that is, the acceleration of the command speed ds has a shape close to a rectangle has been illustrated. However, the configuration to which the anomaly detection device 1 is applicable is not limited depending on the time-series waveform of the command. For example, the anomaly detection device 1 of the present embodiment can also be applied to the waveform of acceleration of the command speed ds when control to set an upper limit on jerk is performed to prevent the occurrence of vibration accompanying sudden acceleration. Furthermore, the anomaly detection device 1 of the present embodiment can also be applied to a configuration in which filtering or the like is performed on the command to suppress the vibration of the mechanical apparatus 2.

In the example of FIG. 2, the command to the servomotor 204 generated by the PLC 301 has been illustrated as the operating condition oc, but the operating condition oc is not limited to the command to the motor 20. The operating condition oc may be anything that includes information on the operation of the mechanical apparatus 2. It is desirable to select, as the operating condition oc, a quantity that has a small correlation with the presence or absence of occurrence of anomaly, and affects the state signal ss or the state quantity sa as a disturbance.

Information included in the condition signal cs is desirably information that is hardly the cause of an anomaly that has occurred in the mechanical apparatus 2. The information included in the condition signal cs is desirably information that can affect the state signal ss as a disturbance. The condition signal generation unit 15 is desirably configured to generate the condition signal cs as described above.

It is desirable that the detected value of the operating condition oc or the condition signal cs do not greatly change between in the presence of occurrence of anomaly and in the absence of occurrence of anomaly. It is desirable that when a difference occurs between the degree of unknownness un in the presence of anomaly and the degree of unknownness un in the absence of anomaly, the difference do not cause a change exceeding a threshold provided for the degree of unknownness un.

The anomaly determination unit 19 outputs a determination result as to whether or not the mechanical apparatus 2 is in an unknown status to the control device 3. When obtaining a determination result that the mechanical apparatus 2 is in an unknown status, the command generation unit 30 outputs the operating condition oc to change the status of the mechanical apparatus 2 to a known status. After obtaining a determination result that the mechanical apparatus 2 is in the known status, based on the value of the degree of unknownness un, the anomaly determination unit 19 may perform anomaly detection based on the degree of unknownness un and the degree of anomaly an. Here, instead of a determination result, the anomaly determination unit 19 may output the degree of unknownness un to the control device 3, and the control device 3 may determine whether the mechanical apparatus 2 is in an unknown status or in a known status.

The anomaly detection device 1 may be provided with a display unit that displays the determination result jr as to whether or not the mechanical apparatus 2 is in an unknown status. When the mechanical apparatus 2 is in an unknown status, the operator may perform an operation to switch to the operating condition oc so as to change the status of the mechanical apparatus 2 to a known status. Here, instead of the determination result jr, the degree of unknownness un may be displayed on the display unit, and the operator may determine whether or not the mechanical apparatus 2 is in an unknown status.

Examples of the information included in the condition signal cs include the outside air temperature, the value of vibration related to the mechanical apparatus 2, the mass of a workpiece handled by the mechanical apparatus 2, and input to the mechanical apparatus 2 to operate the mechanical apparatus 2. Here, the value of vibration related to the mechanical apparatus 2 is a value related to vibration occurring in something in contact with at least part of the mechanical apparatus 2. The value of vibration related to the mechanical apparatus 2 may be a value related to vibration on something that causes vibration or excites vibration in at least part of the mechanical apparatus 2. Examples of the above include a floor or a frame on which the mechanical apparatus 2 is installed and the surrounding air. Examples of a numerical value related to vibration include the amplitude and the frequency of vibration, and a combination of them. The condition signal generation unit 15 can generate the condition signal cs based on these pieces of information. Needless to say, the condition signal cs may be generated by combining a plurality of types of information.

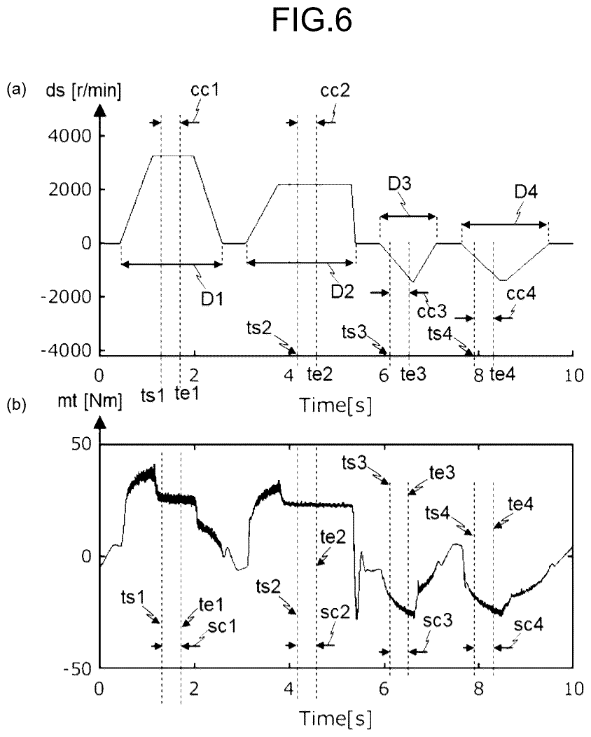

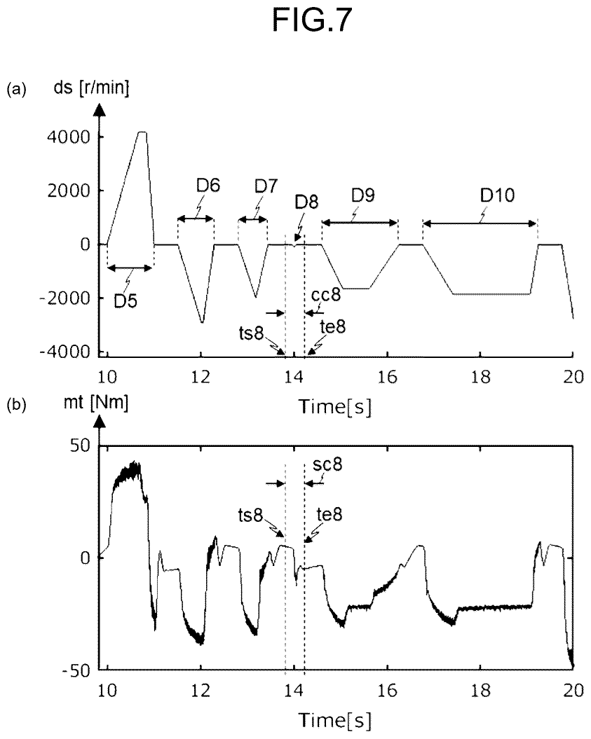

The operations of the state feature generation unit 12 and the condition feature generation unit 16 will be described. FIGS. 6 and 7 are diagrams illustrating an example of time waveforms of the command speed ds for continuous positioning and the motor torque mt according to the present embodiment. FIGS. 6(a) and 7(a) illustrate the time waveform of the command speed ds output as the condition signal cs by the condition signal generation unit 15. FIG. 6(a) illustrates the time waveform in the time range from zero seconds to ten seconds. FIG. 7(a) illustrates the time waveform in the time range from ten seconds to twenty seconds. FIGS. 6(b) and 7(b) illustrate the time waveform of the motor torque mt output as the state signal ss by the state signal generation unit 11. FIG. 6(b) illustrates the time waveform in the time range from zero seconds to ten seconds. FIG. 7(b) illustrates the time waveform in the time range from ten seconds to twenty seconds.

In FIGS. 6(a), 6(b), 7(a), and 7(b), the horizontal axes represent time in seconds (s). Positions denoted by reference numerals on the time axis in FIG. 6(a) and positions denoted by the same reference numerals as the reference numerals in FIG. 6(a) on the time axis in FIG. 6(b) represent the same times. Positions denoted by reference numerals on the time axis in FIG. 7(a) and positions denoted by the same reference numerals as the reference numerals in FIG. 7(a) on the time axis in FIG. 7(b) represent the same times. In FIGS. 6(a) and 7(a), the vertical axes represent the command speed ds in rounds per minute (r/min). In FIGS. 6(b) and 7(b), the vertical axes represent the motor torque mt in newton meters (Nm).

FIG. 5 illustrates positioning performed once, whereas FIGS. 6 and 7 illustrate positioning performed ten times continuously. The ten times of positioning are referred to as positioning D1 to positioning D10. The positioning D1 to the positioning D10 are different from each other in at least one of command speed, acceleration at the time of acceleration, acceleration at the time of deceleration, travel distance, and the like. For example, in the positioning D1, the maximum speed is 3200 r/min, and in the positioning D2, the maximum speed is 2200 r/min.

In the positioning D2, the acceleration at the time of acceleration is large, and the acceleration at the time of deceleration is smaller than that in the positioning D1. In the positioning D2, the absolute value of the acceleration at the time of acceleration is smaller than that in the positioning D1, and the absolute value of the acceleration at the time of deceleration is larger than that in the positioning D1. In the positioning D3, the moving direction of the servomotor 204 is different from that in the positioning D1, and the speed direction is negative. In the positioning D3, the travel distance is smaller than those in the positioning D1 and the positioning D2, and the shape of the time waveform of the command speed ds, that is, the operating condition oc is triangular. Thus, the shape of the command speed ds varies among the positioning D1 to the positioning D10. The operating condition oc generated by the command generation unit 30 varies among the positioning D1 to the positioning D10.

The command generation unit 30 generates the operating condition oc according to the operating situation of the mechanical apparatus 2. For example, when the mechanical apparatus 2 is a conveyance apparatus, the mechanical apparatus 2 is in a situation where it is desirable to improve the efficiency of a conveyance process. Thus, it is desirable for the command generation unit 30 to generate the operating condition oc to complete each time of positioning in the shortest time possible. In a situation where the mechanical apparatus 2 conveys a workpiece that requires reduced shaking, impact, and the like, the command generation unit 30 sets an upper limit on the speed, acceleration, jerk, or the like, and generates the operating condition oc so that the speed, acceleration, jerk, or the like does not exceed the upper limit. For example, in a situation where the mechanical apparatus 2 is an electronic component mounter and the installation position of an electronic component is frequently changed, the command generation unit 30 generates the operating condition oc that varies in travel distance and moving direction for each positioning.

The state feature generation unit 12 generates the state features sc based on the motor torque mt. An example of the motor torque mt is illustrated in FIGS. 6(b) and 7 (b). The state feature generation unit 12 desirably generates the state features sc such that among a plurality of sets of state features sc generated in time series, the number of variables of the state features sc is the same. Here, the number of variables of the state features sc may be, for example, the number of variable parameters or parameters of each set of the state features sc, or the like. The parameters can take different values among the plurality of sets of state features sc. By comparing the plurality of sets of state features sc, changes in the state of the mechanical apparatus 2 are detected. Thus, the comparison can be more easily and accurately performed when the number of variables is the same among the state features sc. The generated state features sc are input to the initial state learning unit 13 and the anomaly degree calculation unit 14. The initial state learning unit 13 executes learning based on the state features sc. The anomaly degree calculation unit 14 calculates the degree of anomaly an.

For example, the state feature generation unit 12 uses, as a set of state features sc1, a time-series signal of the motor torque mt obtained at N time points at equal time intervals between time ts1 and time te1. The number of samples of the motor torque mt at this time, that is, the number of variables of the state features sc is N. The period from time ts1 to time te1 is referred to as a processing time. Specific numerical values will be illustrated. For example, when the sampling period is one millisecond (ms), time te1 is 1501 ms, and time ts1 is 1700 ms, the state features sc are a vector of the number of variables N=100. The state features sc1 described herein are merely an example, and the present embodiment is not limited to this form. The sampling period, processing start time ts1, processing end time te1, and the like can be changed as appropriate. For example, N may be set to a large value, and a set of state features sc may be generated across a plurality of times of positioning. Furthermore, the time-series signals of the state quantity sa, the state features sc, the operating condition oc, the condition features cc, and the like are not limited to signals at equal time intervals. For example, the time intervals of the time-series signals may be set short only in portions where it is necessary to obtain a large amount of data.

The state feature generation unit 12 generates the state features sc sequentially, changing a time to be objected. The motor torque mt from time ts2 to time te2 in FIG. 6 is used as a second set of state features sc2. At this time, to make each of the number of variables of the state features sc equal to N, a value obtained by subtracting time ts2 from time te2 (i.e. te2−ts2), which is the interval between the start time and the end time of the processing, may be made equal to a value obtained by subtracting time ts1 from time te1 (i.e. te1−ts1).

Similarly, the state feature generation unit 12 generates state features sc3 from the motor torque mt obtained during the execution of the positioning D3 illustrated in FIG. 6. The state feature generation unit 12 generates state features sc4 from the motor torque mt obtained during the execution of the positioning D4. The state feature generation unit 12 generates state features sc8 from the motor torque mt obtained during the execution of the positioning D8 illustrated in FIG. 7.

In the example of FIGS. 6 and 7, a plurality of processing times in which the state features sc1 to sc8 are generated do not overlap each other, but the present embodiment is not limited to cases where times in which to generate the state features sc do not overlap each other. For example, the relationship between time ts1 and time ts2 may be either before and after or the same time, and can be freely selected.

As described above, the plurality of processing times may overlap each other. For example, a time in which to perform sampling, that is, a processing time may be regarded as one window, and sampling may be performed, sliding the window, shifting the start time of the processing time by a sampling time that is the time interval of the sampling performed at equal intervals, to obtain the state features sc. For example, when the sampling time is one millisecond and the number of variables N of the state features sc, which is the sampling number in one window, is 100, 99% of the number of samples of the calculated state features sc are duplicate and 1% are different. A method of performing sampling by a window slid sequentially for a predetermined number of samples in this manner is called a sliding window method. This sliding window method may be adopted.

In the example of FIGS. 6 and 7, the state signal ss obtained in time series is sampled for a predetermined number of samples and output as one set of state features sc. A method of generating the state features sc different from the example of FIGS. 6 and 7 will be illustrated. For example, a plurality of statistics is calculated from the time-series condition signal cs as one set of state features sc or condition features cc. Numerical values obtained by applying a statistical algorithm to the time-series signal detected as the state quantity sa may be used as statistics. Alternatively, values obtained by summarizing the features of a certain number of pieces of sample data may be used. Here, for the statistical algorithm and the summarizing method, there is a plurality of methods. Examples of a statistic include an average, a standard deviation, a variance, a root mean square, a maximum value, a minimum value, a peak value, a crest factor, kurtosis, and skewness.

Alternatively, frequency analysis may be performed on the time-series signal to obtain the state features sc or the condition features cc. For example, the gain of a specific frequency, the phase of a specific frequency, or the like may be measured by frequency analysis to obtain the state features sc or the condition features cc. When processing such as the calculation of statistics or frequency analysis is performed at the time of calculating the state features sc or the condition features cc, the numbers of samples during the processing times of the signal used to calculate the features do not necessarily need to be the same. In contrast, the numbers of variables of the state features sc or the condition features cc to be calculated are desirably the same.

The state feature generation unit 12 arranges a predetermined number of samples of the state signal ss obtained in time series and outputs the arranged samples as one set of state features sc. In this case, the state features sc1, the state features sc2, the state features sc3, the state features sc4, and the state features sc8 are vectors consisting of a plurality of variables, including information on the state of the mechanical apparatus 2, according to the respective operating conditions oc.

For example, the state features sc1 and the state features sc2 differ in the speed of the servomotor 204. The state features sc3 include a time in which the speed of the servomotor 204 is not constant and the servomotor 204 is accelerating. The positioning D4 includes a time in which the servomotor 204 accelerates, a time in which the speed is constant, and a time in which the servomotor 204 decelerates. For the state features sc4, sampling is performed on the time in which the servomotor 204 accelerates. For the state features sc8, the travel distance of the servomotor 204 is minute, and the maximum speed is low.

In the mechanical apparatus 2 operated under various operating conditions oc like this, it is difficult to perform learning on a combination of all the operating conditions oc in advance. It is possible to adopt a method of extracting data in a time when the servomotor 204 is moving at a speed included in a speed range specified in advance, or in a time when the servomotor 204 is moving at an acceleration included in a predetermined acceleration range. This method allows the obtainment of stable data, but has a problem that processing to extract the signal takes time and effort. Furthermore, depending on the operating condition oc, there may be cases where anomalies cannot be detected.

As far as the inventors know, there have been no methods to quantitatively evaluate the degree of discrepancy between an operating status that is an object of detection measured as a large number of variables obtained in time series and an operating status at the time of learning measured as a large number of variables obtained in time series in this manner. Furthermore, the problem that it is difficult to quantitatively evaluate the discrepancy between the above-described two statuses has not been recognized. Here, in the example of FIGS. 6 and 7, an operating status that is an object of detection is expressed as the time-series detection condition signal dcs. An operating status in an initial learning time is expressed as the initial learning condition signal lcs.

The condition feature generation unit 16 generates the initial learning condition features lcc, based on the initial learning condition signal lcs. The condition feature generation unit 16 generates the detection condition features dcc, based on the detection condition signal dcs. In the example of FIG. 6, the command speed ds illustrated in FIGS. 6(a) and 7(a) is used as the condition signal cs. Then, the condition feature generation unit 16 uses the command speed ds included in each of the plurality of processing times as the detection condition features dcc.

The condition feature generation unit 16 uses, as condition features cc1, a time-series signal of a set of command speeds ds in the period from time ts1 to time te1 in which the positioning D1 has been performed. The condition feature generation unit 16 uses, as condition features cc2, a set of command speeds ds in the period from time ts2 to time te2 in which the positioning D2 has been performed. The condition feature generation unit 16 uses, as condition features cc3, a set of command speeds ds in the period from time ts3 to time te3 in which the positioning D3 has been performed. The condition feature generation unit 16 uses, as condition features cc4, a set of command speeds ds in the period from time ts4 to time te4 in which the positioning D4 has been performed (represented as the condition features cc4 in FIG. 6). The condition feature generation unit 16 uses, as condition features cc8, a set of command speeds ds in the period from time ts8 to time te8 in which the positioning D8 has been performed. Here, each set of the condition features cc1, the condition features cc2, the condition features cc3, the condition features cc4, and the condition features cc8 may be used as the detection condition features dcc or as the initial learning condition features lcc.

As described above, detection condition features dcc1, detection condition features dcc2, detection condition features dcc3, detection condition features dcc4, and detection condition features dcc8 generated by the condition feature generation unit 16 sequentially correspond to detection state features dsc1, detection state features dsc2, detection state features dsc3, detection state features dsc4, and detection state features dsc8, respectively. Here, the correspondence between the detection condition features dcc and the detection state features dsc means that the state signal ss and the operating condition oc used to generate them, respectively, have been detected during the same processing times.

In the example of FIGS. 6 and 7, to facilitate understanding, the sampling frequencies of the command speed ds and the motor torque mt are the same. In addition, the number of variables of one set of state features sc and the number of variables of one set of condition features cc are the same. However, the present embodiment is not limited to this form. For example, the sampling frequency of the condition signal cs and the sampling frequency of the state signal ss may be different. Furthermore, for example, the number of variables of one set of state features sc and the number of variables of one set of condition features cc may be different from each other. If the detection state signal dss and the detection condition signal dcs used to calculate the detection state features dsc and the detection condition features dcc corresponding to each other, respectively, are obtained during the same processing times, the degree of anomaly an and the degree of unknownness un are calculated based on the data obtained in the same processing times, so that anomaly detection can be performed more accurately.

The method by which the condition feature generation unit 16 generates the condition features cc and the method by which the state feature generation unit 12 generates the state features sc may be the same or different. For example, for the method of generating the condition features cc, the calculation of statistics may be used, and as the method of generating the state features sc, frequency analysis may be used.

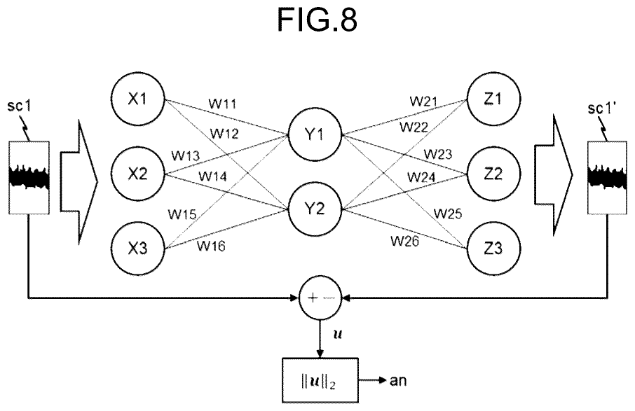

The initial state learning unit 13 executes learning based on the initial learning state features lsc, and outputs the results of the learning as the initial state learning results slr. The initial condition learning unit 17 executes learning based on the initial learning condition features lcc, and outputs the results of the learning as the initial condition learning results clr. FIG. 8 is a diagram illustrating an example of an autoencoder according to the present embodiment.

The autoencoder is a type of neural network model. The autoencoder illustrated in FIG. 8 includes an input layer consisting of nodes X1 to X3, an intermediate layer consisting of nodes Y1 and Y2, and an output layer consisting of nodes Z1 to Z3. The nodes of the autoencoder in FIG. 8 are connected by a plurality of edges with weights W11 to W26 given as parameters. According to the autoencoder of FIG. 8, based on values input to the input layer, values calculated with functions set to the edges are transferred to the nodes in the next layer connected via the edges, and results can be finally obtained from the output layer.

That is, the neural network constitutes one complicated function as a whole. The autoencoder is a type of unsupervised learner, and learns the parameters (weights) so that data output from the output layer approaches data input to the input layer. A large number of pieces of data to be input are prepared. By adjusting the parameters, which are weights, for each piece of data to reduce the error between input and output, the network learns the characteristics of an input signal.

In the example of FIG. 8, to facilitate understanding, the number of the nodes in the input layer is three, and the number of the nodes in the output layer is three. The numbers of the input and output nodes need to be made equal to the number of variables N of an input to be objected (e.g. N=100 in the example of FIG. 6). The numbers of the input and output nodes may each be, for example, 100 in the example of FIGS. 6 and 7. For the sake of explanation, in the example of FIG. 8, the number of the nodes in the intermediate layer is two, and the total number of intermediate layers is one, but the number of nodes in the intermediate layer and the number of intermediate layers are not limited to them.

The initial state learning unit 13 trains the neural network such that when the state features sc1, which are the initial learning state features lsc, are input to the network, estimated values sc1′ of the state features sc1 are obtained as output. Then, the initial state learning unit 13 outputs the trained neural network model as the initial state learning results slr. The initial state learning results slr only need to be able to specify the model, and may be, for example, the model parameters, the model structure, etc. The initial condition learning unit 17 trains the neural network such that when the condition features cc1, which are the initial learning condition features lcc, are input to the network, estimated values cc1′ of the condition features cc1 are obtained as output. The initial condition learning unit 17 outputs the trained neural network model as the initial condition learning results clr. The initial condition learning results clr only need to be able to specify the model, and may be, for example, the model parameters, the model structure, etc.

In FIG. 8, the configuration using the autoencoder has been described as an example of the initial state learning unit 13 and the initial condition learning unit 17, but the present embodiment is not limited to this configuration. Examples of the configuration of the initial state learning unit 13 and the initial condition learning unit 17 different from the autoencoder include a self-organizing map (SOM), the Mahalanobis-Taguchi (MT) method, principal component analysis (PCA), a one-class support vector machine (OCSVM), the k-nearest neighbors method, and Isolation Forest. Any method different from the methods illustrated above may be used as the learning method of the initial state learning unit 13 or the initial condition learning unit 17 as long as the method is a learning method that can learn features input in advance and evaluate how much the characteristics of features obtained after the learning deviate from the characteristics of the learned features.

In the example of FIG. 8, the initial state learning unit 13 and the initial condition learning unit 17 have been described as having the same structure. The structures of the initial state learning unit 13 and the initial condition learning unit 17 do not need to be the same. Different learning methods may be combined. However, when the state features sc and the condition features cc maintain the same complexity, it is desirable to configure the initial state learning unit 13 and the initial condition learning unit 17 by learning methods having the same level of explainability. For example, it is desirable that the neural networks of the initial state learning unit 13 and the initial condition learning unit 17 have the same number of nodes and the same number of edges. In addition, it is desirable that the initial state learning unit 13 and the initial condition learning unit 17 have the same number of pieces of input data.

The operations of the anomaly degree calculation unit 14 and the unknownness degree calculation unit 18 will be described. The anomaly degree calculation unit 14 calculates the degree of anomaly an based on the initial state learning results slr and the detection state signal dss. The degree of anomaly an may be the degree of discrepancy between the initial learning state signal lss and the detection state signal dss. For example, the anomaly degree calculation unit 14 inputs the detection state features dsc to a model configured using the initial state learning results slr. Then, the anomaly degree calculation unit 14 may calculate the degree of discrepancy between the initial learning state features lsc and the detection state features dsc, and use this degree of discrepancy, information indicating the degree of discrepancy, or the like as the degree of anomaly an.

As illustrated in FIG. 8, when the autoencoder is used for learning, for example, the difference between the state features sc input to the autoencoder and the estimated values of the state features sc output from the autoencoder may be used as the degree of anomaly an. Since both the state features sc and the estimated values of the state features sc are vector quantities, the difference between the two is also a vector quantity. In the example of FIG. 8, to evaluate the degree of anomaly an as a scalar value, the square root of the sum of the squares of the residual vector, which is the difference between the two, is used as the degree of anomaly an.

As another method of calculating the degree of anomaly an using the autoencoder, there is a method of using the difference between values in the intermediate layer at the time of learning and values in the intermediate layer at the time of evaluation as the degree of anomaly an, instead of using the difference between input and output as described above. When the intermediate layer has one node, the difference between a mean value in the intermediate layer at the time of learning and a value in the intermediate layer at the time of inference (at the time of detection) may be calculated, and the magnitude of the difference may be used as the degree of anomaly an. When the intermediate layer has a plurality of nodes, similarly to the case of calculating the difference between input and output described above, the square root of the sum of the squares of the residual vector obtained by subtracting a mean value in the intermediate layer at the time of learning from each value in the intermediate layer at the time of inference is used as the degree of anomaly an.

When a self-organizing map is used as the learning method, minimum quantization error (MQE) may be used as the degree of anomaly an. When principal component analysis is used, the T2 statistic or the Q statistic may be used as the degree of anomaly an. When a one-class support vector machine is used, the distance from the origin in a mapped space may be used as the degree of anomaly an. When the k-nearest neighbors method is used, the distance between a feature to be evaluated and k learned features close to the feature to be evaluated may be used as the degree of anomaly an.

The unknownness degree calculation unit 18 calculates the degree of unknownness un, which is the degree of discrepancy between the initial learning condition signal lcs and the detection condition signal dcs, based on the initial condition learning results clr and the detection condition signal dcs. For example, the unknownness degree calculation unit 18 configures a model using the initial condition learning results clr. Then, the unknownness degree calculation unit 18 inputs the detection condition features dcc to the configured model, and calculates the degree of discrepancy between output from the configured model and the detection condition features dcc. This degree of discrepancy may be used as the degree of unknownness un.

As illustrated in FIG. 8, when the autoencoder is used for learning, the difference between the detection condition features dcc input and the estimated values output from the model may be used as the degree of unknownness un. Since both the detection condition features dcc and the estimated values of the detection condition features dcc output from the model are vector quantities, the difference between the vectors is also a vector. Thus, to evaluate the degree of unknownness un as a scalar value, the square root of the sum of the squares of the residual vector, which is the difference between the vectors, may be used as the degree of unknownness un.

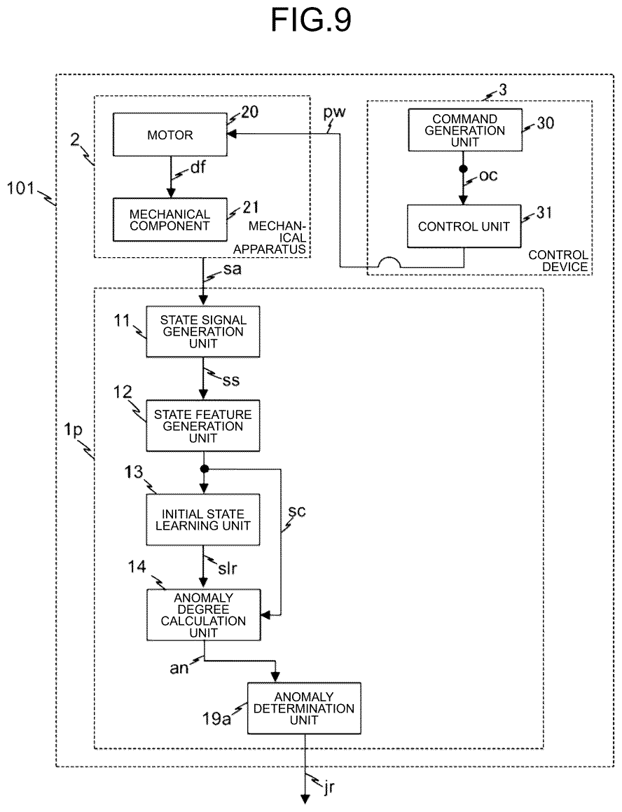

FIG. 9 is a diagram illustrating an example of a configuration in which the anomaly determination unit 19 is omitted from the anomaly detection device 1 according to the present embodiment. The configuration obtained by omitting the anomaly determination unit 19 from the configuration of the anomaly detection device 1 is referred to as an anomaly detection device 1p. In FIG. 9, the same components and signals as those in FIG. 1 are denoted by the same reference numerals.

The anomaly detection device 1p is obtained by omitting four components, the condition signal generation unit 15, the condition feature generation unit 16, the initial condition learning unit 17, and the unknownness degree calculation unit 18, from the configuration of the anomaly detection device 1 illustrated in FIG. 1. The anomaly detection device 1p includes an anomaly determination unit 19a instead of the anomaly determination unit 19 of the anomaly detection device 1 illustrated in FIG. 1. A point of difference between the anomaly determination unit 19a and the anomaly determination unit 19 will be described. The anomaly determination unit 19 performs a determination based on the degree of anomaly an and the degree of unknownness un. In contrast, the anomaly determination unit 19a performs a determination based on the degree of anomaly an without using the degree of unknownness un.

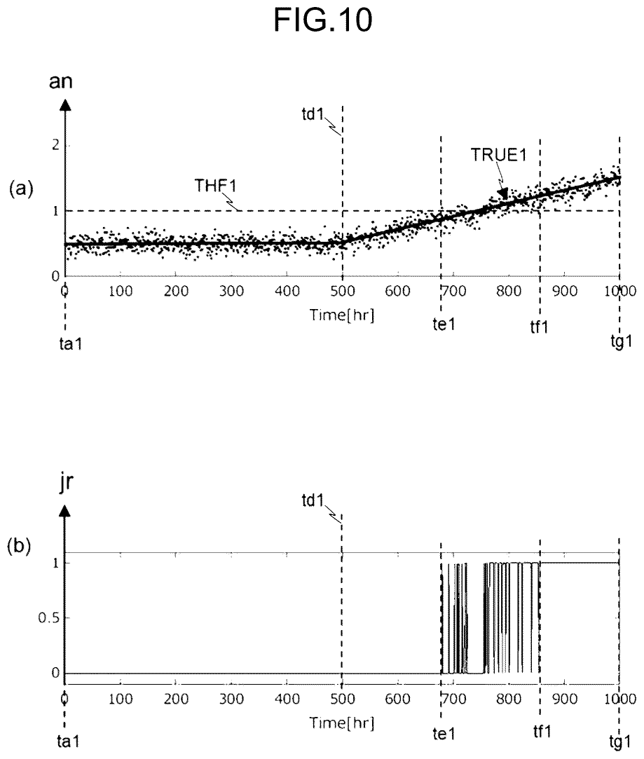

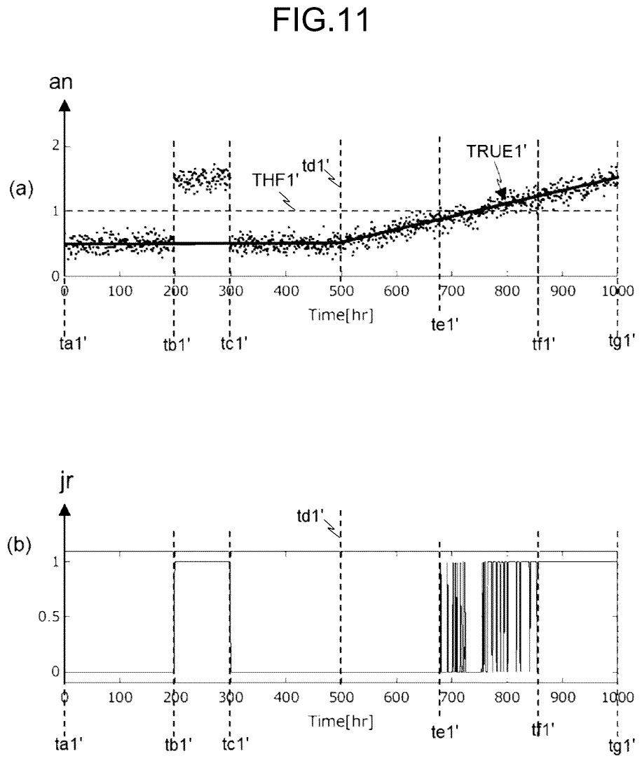

The anomaly detection device 1p is the same as the anomaly detection device 1 except for the above point. FIG. 10 is an example of temporal changes in the degree of anomaly an and the determination result jr generated by the configuration in which the anomaly determination unit 19 is omitted from the anomaly detection device 1 according to the present embodiment. In other words, FIG. 10 is an example of temporal changes in the degree of anomaly an and the determination result jr generated by the anomaly detection device 1p. FIG. 11 is an example, which is different from that in FIG. 10, of temporal changes in the degree of anomaly an, the degree of unknownness un, and the determination result jr generated by the configuration in which the anomaly determination unit 19 is omitted from the anomaly detection device 1 according to the present embodiment. In other words, FIG. 11 is an example of temporal changes in the degree of anomaly an and the determination result jr generated by the anomaly detection device 1p.

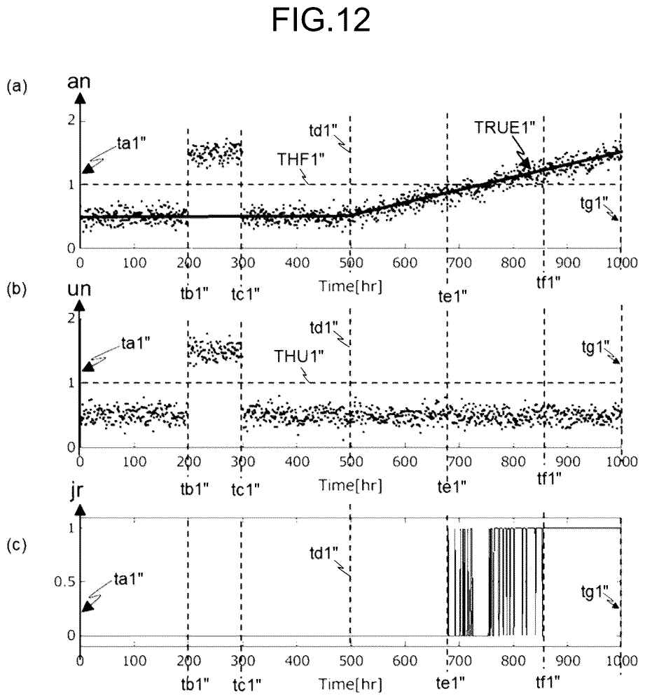

The determination result jr in FIGS. 10 and 11 is the determination result jr output by the anomaly determination unit 19a of the anomaly detection device 1p. In contrast, FIG. 12 described later is an operation in which the anomaly determination unit 19 of the anomaly detection device 1 performs anomaly determination using the degree of unknownness un. The effect of using the degree of unknownness un will be described by comparing the two.

In FIGS. 10 and 11, the horizontal axes represent time in hours (hr). FIGS. 10(a) and 11(a) are temporal changes in the degree of anomaly an. In FIGS. 10(a) and 11(a), the vertical axes represent the degree of anomaly an. FIGS. 10(b) and 11(b) are temporal changes in the determination result jr. In FIGS. 10(b) and 11(b), the vertical axes represent the determination result jr. In FIGS. 10(a) and 10(b), two positions denoted by the same reference numeral on the time axes represent the same time. In FIGS. 11(a) and 11(b), two positions denoted by the same reference numeral on the time axes represent the same time.

In the example of FIG. 10, the value of the degree of anomaly an is plotted hourly from time ta1, which is the time when a time of ta1 has elapsed since the start of the operation of the anomaly detection device 1p, to time tg1. Assume that the initial state learning on the mechanical apparatus 2 has been completed between the start of the operation of the anomaly detection device 1p and time ta1. Between time ta1 and time td1, the degree of anomaly an includes some variation but all are plotted between zero and one, exhibiting characteristics of mostly small temporal changes. Between time td1 and time tg1, the degree of anomaly an gradually increases as the operating time elapses. This reflects the gradual deterioration of the mechanical apparatus 2 from time td1 forward. At time te1, the degree of anomaly an exceeds one for the first time. From time tf1 forward, all the degrees of anomaly an exceed one.

In the example of FIG. 10(a), a threshold THF1 of the degree of anomaly an used by the anomaly determination unit 19a when calculating the determination result jr is set to one. When the value of the degree of anomaly an exceeds the threshold THF1, the anomaly determination unit 19a determines that the state is anomalous. When the value of the degree of anomaly an is equal to or less than the threshold THF1, the anomaly determination unit 19a determines that the state is normal.

Further, in FIG. 10(a), the true degree of anomaly TRUE1 of the mechanical apparatus 2 is illustrated by a thick solid line. The true degree of anomaly TRUE1 is the degree of anomaly an based on the state quantity sa from which the effects of disturbances have been completely eliminated, and is the virtual degree of anomaly an for clear explanation. The true degree of anomaly TRUE1 is the degree of anomaly an obtained when the state quantity sa for detection is obtained at each time point with the effects of disturbances completely eliminated, and further, based on this state quantity sa, the detection state features dsc and the degree of anomaly an are calculated. An example of the disturbances is, for example, a change in the operating condition oc of the mechanical apparatus 2 between the initial state learning time and the detection time, or the like. In this case, the disturbance can be eliminated by returning the operating condition oc to that at the initial state learning time to measure the state quantity sa for detection. Even when it is actually difficult or impossible to eliminate disturbances, here, the degree of anomaly an calculated when it is assumed that the true degree of anomaly can be calculated with disturbances eliminated is referred to as the true degree of anomaly TRUE1. The true degree of anomaly TRUE1 is different from the degree of anomaly an estimated by the anomaly detection device 1p. The true degree of anomaly TRUE1 is not affected by disturbances such as the operating condition oc. It can be said that the ideal operation of typical anomaly detection devices is to estimate the true degree of anomaly TRUE1 to detect anomalies. In other words, when the degree of anomaly an correctly represents the state of the mechanical apparatus 2, the degree of anomaly an has the same value as the true degree of anomaly TRUE1. It is ideal to detect the true degree of anomaly TRUE1. However, the true degree of anomaly TRUE1 cannot be detected in many cases since actual anomaly detection devices are affected by disturbances. In FIG. 10, the true degree of anomaly TRUE1 is plotted to facilitate understanding. The true degree of anomaly TRUE1 does not necessarily need to be calculated.

In FIG. 10(b), temporal changes in the determination result jr by the anomaly detection device 1p are plotted hourly. When the mechanical apparatus 2 is normal, the determination result jr is zero, and when the mechanical apparatus 2 is anomalous, the determination result jr is one. The form of the output of the determination result jr by the anomaly determination unit 19a is not limited to this form. The form of the output of the determination result jr may be one that allows the determination of whether the state is normal or anomalous from the determination result jr. Alternatively, the form of the output of the determination result jr may be one that allows the degree of anomaly to be known.

Forms of the output of the determination result jr include not only the output of a signal including information on the determination result jr, the display (including the non-display) of the determination result jr to the operator, the issuance of an alert (e.g., a sound such as a siren, a red light, or the like), and the stopping of an alert (including the non-output of an alert), but also the stopping of the mechanical apparatus 2, the reduction of the operating speed of the mechanical apparatus 2, the stopping of a device connected to the mechanical apparatus 2, and an instruction to activate a maintenance device of the mechanical apparatus 2.

In the example of FIG. 10(b), the determination result jr from time ta1 to time te1 is a normal value that is a value indicating normality. That is, the value of the determination result jr is zero. At time te1, the determination result jr changes from the normal value to an anomalous value at least once. From time te1 to time tf1, the determination result jr contains both the normal value and the anomalous value due to variations in the degree of anomaly an.

According to FIG. 10(a), the mechanical apparatus 2 starts to deteriorate at time td1, and the deterioration gradually progresses from time td1 forward. The determination result jr at and after time td1 being the anomalous value does not correspond to false detection (erroneous determination of a normal state as anomalous). As described above, when the mechanical apparatus 2 is in the situation illustrated in FIG. 10, the anomaly detection device 1p can detect anomalies without causing false detection. That is, when the mechanical apparatus 2 is in the situation illustrated in FIG. 10, no false detection occurs even without using the degree of unknownness un for anomaly detection. In addition, the anomaly detection device 1p can output the degree of anomaly an close to the true degree of anomaly TRUE1.

FIG. 11 will be described. As described above, FIG. 11 is an example of results detected by the anomaly detection device 1p. The time period illustrated in FIG. 11 and the time period illustrated in FIG. 10 are different from each other. In the example of FIG. 11, deterioration of the mechanical apparatus 2 starts at time td1′, and the mechanical apparatus 2 gradually deteriorates from time td1′ forward. Between time tb1′ and time tc1′, the speed of the motor 20 is changed to a value different from the speed of the motor 20 at the time of the initial state learning. In the period between time ta1′ and time tg1′ except the period from time tb1′ to time tc1′, the motor speed is the same as the motor speed at the time of the learning.

FIG. 11(a) illustrates temporal changes in the degree of anomaly an. FIG. 11(b) illustrates temporal changes in the determination result jr. The horizontal axes in FIGS. 11(a) and 11(b) represent time in hours (hr). On the time axis of FIG. 11(a) and the time axis of FIG. 11(b), times denoted by the same reference numerals are the same times. The example of FIG. 11 illustrates data from time ta1′, which is the time when a time of ta1′ has elapsed since the start of the operation of the anomaly detection device 1p, to time tg1′. Description will be given on the assumption that the initial state learning unit 13 has completed the initial state learning before time ta1′.

In FIG. 11(a), the vertical axis represents the degree of anomaly an, and data points of the degree of anomaly an are plotted hourly. Between time ta1′ and time tb1′, and between time tc1′ and time td1′, the degree of anomaly an includes some variation but all are plotted in the range from zero to one, exhibiting characteristics of mostly small temporal changes.

Between time td1′ and time tg1′, the degree of anomaly an includes some variation but exhibits the characteristics of gradually increasing with the lapse of the operating time. The difference between FIG. 10(a) and FIG. 11(a) will be described. In FIG. 11(a), the degree of anomaly an exceeds one between time tb1′ and time tc1′. In contrast, in FIG. 10(a), the degree of anomaly an is maintained at values lower than one between time ta1 and time td1. The increase in the degree of anomaly an between time tb1′ and time tc1′ in FIG. 11(a) is not due to the deterioration of the mechanical apparatus 2. This increase in the degree of anomaly an is due to a change in the operating condition between time tb1′ and time tc1′ from that at the time of the initial learning, that is, a change in the operating condition oc.

As illustrated in FIG. 11(a), a threshold THF1′ for the degree of anomaly an is set to one. The threshold THF1′ is determined from the distribution of the degree of anomaly an when the mechanical apparatus 2 is normal. Further, in FIG. 11(a), the true degree of anomaly TRUE1′ of the mechanical apparatus 2 is illustrated by a thick solid line. The description of the true degree of anomaly TRUE1′ of FIG. 11 is the same as the description of the true degree of anomaly TRUE1 described in the description of FIG. 10, and thus is omitted.

In FIG. 11(b), the determination result jr is plotted on the vertical axis. The determination result jr in FIG. 11(b) is illustrated with data points obtained hourly connected by a line. In FIG. 11(b), as an example of the form of the determination result jr, when the mechanical apparatus 2 is normal, the value of the determination result jr is plotted as zero, and when the mechanical apparatus 2 is anomalous, the value of the determination result jr is plotted as one.

The anomaly determination unit 19a compares the degree of anomaly an in FIG. 10(a) with the threshold THF1′. When the degree of anomaly an is less than or equal to the threshold THF1′, the anomaly determination unit 19a determines that the state of the mechanical apparatus 2 is normal, and sets the determination result jr to zero. In contrast, when the degree of anomaly an exceeds the threshold THF1′, the anomaly determination unit 19a considers that the state of the mechanical apparatus 2 is anomalous, and sets the determination result jr to one. Here, the degree of anomaly an being less than or equal to the threshold THF1′ means that the value of the degree of anomaly an is less than the threshold THF1′ or the value of the degree of anomaly an is equal to the threshold THF1′.

As illustrated in FIG. 11(b), the anomaly determination unit 19a outputs zero as a value indicating normality as the determination result jr in two time periods between time ta1′ and time tb1′ and between time tc1′ and time te1′. Since the degree of anomaly an exceeds one between time tb1′ and time tc1′, the anomaly determination unit 19a outputs a value of one indicating anomaly as the determination result jr.

As described by comparing FIGS. 10 and 11, in the example of FIG. 10, the operating condition oc at the time of the detection is maintained the same as that at the time of the initial learning. In contrast, in the example of FIG. 11, the operating condition oc is changed from that at the time of the initial state learning in a partial time period of the detection time. In the example of FIG. 10, no false detection occurs in the results of detection by the anomaly detection device 1p. In contrast, in the example of FIG. 11, false detection has occurred in the results of detection by the anomaly detection device 1p due to the change in the operating condition oc from that at the time of the initial learning. Here, an event of outputting an erroneous determination result that the mechanical apparatus 2 is anomalous when the mechanical apparatus 2 is normal is referred to as false detection.

According to the comparison of FIGS. 10 and 11, when the detection time includes a time period in which the operating condition oc is different between the time of the initial state learning and the time of the detection, false detection may occur in the anomaly detection device 1p that outputs the determination result jr without using the degree of unknownness un.

With reference to FIG. 12, the operation of the anomaly determination unit 19 of the anomaly detection device 1 in the present embodiment will be described. FIG. 12 is a diagram illustrating temporal changes in the degree of anomaly an, the degree of unknownness un, and the determination result jr generated by the anomaly detection device 1 according to the present embodiment. FIG. 12 illustrates the temporal changes when the mechanical apparatus 2 gradually deteriorates from time td1″ forward. Between time tb1″ and time tc1″ in FIG. 12, the speed of the motor 20 is changed to a setting different from that at the time of the initial learning. Between time ta1″ and time tb1″ and between time tc1″ and time tg1″ in FIG. 12, the speed of the motor 20 is set the same as that at the time of the initial learning.

FIG. 12(a) illustrates temporal changes in the degree of anomaly an. FIG. 12(b) illustrates temporal changes in the degree of unknownness un. FIG. 12(c) illustrates temporal changes in the determination result jr. In FIGS. 12(a), 12(b), and 12(c), the horizontal axes represent time in hours (hr). Of the times on the time axes in FIGS. 12(a), 12(b), and 12(c), times denoted by the same reference numerals indicate the same times. The example of FIG. 12 illustrates data from time ta1″, which is the time when a time of ta1″ has elapsed since the start of the operation of the anomaly detection device 1, to time tg1″. Assume that the initial learning, that is, the initial state learning and the initial condition learning on the mechanical apparatus 2 have been completed before time ta1″.

For the degree of anomaly an in FIG. 12(a), data points are plotted hourly. Between time ta1″ and time tb1″ and between time tc1″ and time td1″ in FIG. 12(a), the value of the degree of anomaly an includes some variation but all are plotted in the range between zero and one, and changes in the value are small. Between time td1″ and time tg1″, the degree of anomaly an gradually increases with the lapse of time.

In FIG. 12(a), the degree of anomaly an exceeds one between time tb1″ and time tc1″. The increase in the degree of anomaly an in this time period is similar to the description of the degree of anomaly an between time tb1′ and time tc1′ in FIG. 11(a). That is, the increase in the degree of anomaly an between time tb1″ and time tc1′ in FIG. 12(a) is not an increase in the degree of anomaly an due to the occurrence of deterioration of the mechanical apparatus 2, but is due to a change in the operating condition, in other words, the operating condition oc. That is, the increase in the degree of anomaly an is due to a change in the speed of the motor 20 from that at the time of the initial learning, between time tb1″ and time tc1″ in FIG. 12, similarly between time tb1′ and time tc1′ in FIG. 11.

In FIG. 12, the mechanical apparatus 2 does not suffer deterioration between time tb1″ and time tc1″. Thus, the characteristics of the state features sc obtained between time tb1″ and time tc1″ are different from the characteristics of the state features sc at the time of the initial state learning, although the mechanical apparatus 2 is not in an anomalous state. Due to the change in the state features sc from those at the time of the initial learning, the degree of anomaly an illustrated in FIG. 11(a) has large values exceeding THF1″.

The degree of anomaly an in FIG. 12 becomes a value exceeding one at time te1″, and all the degrees of anomaly an exceed one at times after time tf1″. As illustrated in FIG. 12(a), a threshold THF1″ for the degree of anomaly is set to one. The threshold THF1″ may be determined from the distribution of the degree of anomaly an or the like when the mechanical apparatus 2 is normal. Furthermore, FIG. 12(a) illustrates, by a thick solid line, the true degree of anomaly TRUE1″ of the mechanical apparatus 2 that is not affected by disturbances such as the operating condition oc, unlike the degree of anomaly an output by the anomaly detection device 1. The description of the true degree of anomaly TRUE1″ is similar to the description of the true degree of anomaly TRUE1 in FIG. 10.

The vertical axis in FIG. 12(b) is the degree of unknownness un calculated by the unknownness degree calculation unit 18. In FIG. 12(b), between time ta1″ and time tb1″ and between time tc1″ and time tg1″, all the degrees of unknownness un are plotted between zero and one. In contrast, between time tb1″ and time tc1″, all the degrees of unknownness un are plotted between one and two. As illustrated in FIG. 12(b), a threshold THU1″ for the degree of unknownness un is set to one.

The threshold THU1″ may be determined from the distribution of the degree of unknownness un or the like when the initial condition learning is performed. By determining the threshold THU1″ from the distribution of the degree of unknownness un at the time of executing the initial condition learning, it can be determined whether or not the degree of anomaly an accurately represents the state of the mechanical apparatus 2 from the degree of unknownness un. For example, when the discrepancy between the degree of unknownness un calculated in the detection time and the distribution of the degree of unknownness un at the time of the initial condition learning is large, the anomaly determination unit 19 may determine from the degree of unknownness un that the degree of anomaly an does not accurately represent the state of the mechanical apparatus 2. For example, when the discrepancy between the calculated degree of unknownness un and the distribution of the degree of unknownness un at the time of the initial condition learning is small, the anomaly determination unit 19 may determine from the degree of unknownness un that the degree of anomaly an accurately represents the state of the mechanical apparatus 2.

The vertical axis in FIG. 12(c) indicates the determination result jr of the presence or absence of an anomaly in the mechanical apparatus 2 determined by the anomaly determination unit 19. In the example of FIG. 12(c), the determination result jr is plotted with data points calculated hourly connected by a line. As an example of the form of the output of the determination result jr, the determination result jr is set to zero when the state of the mechanical apparatus 2 is normal, and the determination result jr is set to one when the state of the mechanical apparatus 2 is anomalous. The form of the output of the determination result jr in the present embodiment is not limited to this form.

The anomaly determination unit 19 compares the degree of anomaly an illustrated in FIG. 12(a) with the threshold THF1″. Further, the anomaly determination unit 19 compares the degree of unknownness un illustrated in FIG. 11(b) with the threshold THU1″. When the degree of anomaly an exceeds the threshold THF1″ and the degree of unknownness un is less than or equal to the threshold THU1″, the anomaly determination unit 19 regards the state of the mechanical apparatus 2 as anomalous and sets the determination result jr to one.

In a case other than the above, the anomaly determination unit 19 regards the state of the mechanical apparatus 2 as normal, and sets the determination result jr to zero. Here, the case other than the above is at least one of a first case or a second case described below. The first case is a case where the degree of anomaly an is less than or equal to the threshold THF1″. The second state is a case where the degree of unknownness un exceeds the threshold THU1″.

The anomaly determination unit 19 uses the degree of unknownness un when outputting the determination result jr. As illustrated in FIG. 12(c), the anomaly determination unit 19 outputs a value of zero indicating normality as the determination result jr between time ta1″ and time te1″. No false detection has occurred in the anomaly detection device 1. In contrast, the anomaly determination unit 19a described in FIG. 11 does not use the degree of unknownness un. As illustrated in FIG. 11(b), the anomaly determination unit 19a generates a value of one indicating anomaly as the determination result jr between time tb1′ and time tc1′. False detection has occurred in the anomaly detection device 1a. Thus, according to the description comparing FIG. 12 and FIG. 11, the anomaly detection device 1 of the present embodiment can perform anomaly detection with less false detection by using the degree of unknownness un.

Instead of the configuration of the anomaly determination unit 19 that sets the respective thresholds for the degree of anomaly an and the degree of unknownness un as described above, the anomaly detection device 1 with fewer occurrences of false detection may be configured to reflect a difference in the operating condition oc in the output of the determination result jr, using a value that has undergone the processing of dividing the degree of anomaly an by the degree of unknownness un (a value obtained by dividing the degree of anomaly an by the degree of unknownness un, that is, an/un). For example, a threshold is provided for a value obtained by dividing the degree of anomaly an by the degree of unknownness un. When this value exceeds the threshold, it is determined that the state is anomalous. When the value obtained by dividing the degree of anomaly an by the degree of unknownness un is less than or equal to the threshold, it is determined that the state is normal.

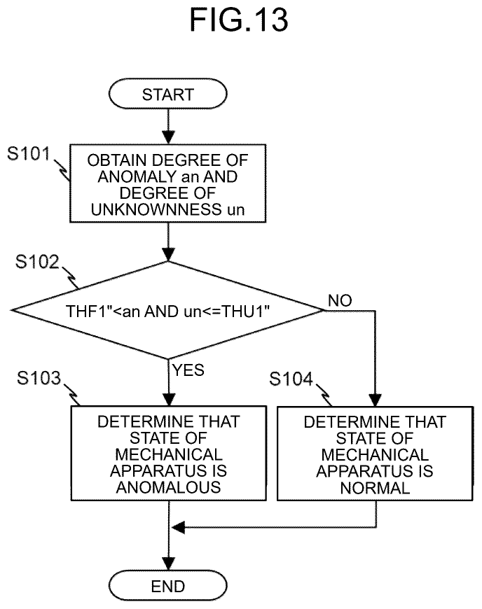

FIG. 13 is a diagram illustrating an example of an operation flow of the anomaly determination unit 19 according to the present embodiment. In step S101, the anomaly determination unit 19 obtains a set of the degree of anomaly an calculated by the anomaly degree calculation unit 14 and the degree of unknownness un calculated by the unknownness degree calculation unit 18. The degree of anomaly an and the degree of unknownness un in the set desirably correspond to each other. In other words, the degree of anomaly an and the degree of unknownness un are desirably based on information obtained during the same detection time. That is, the detection state signal dss used to generate the degree of anomaly an and the detection condition signal dcs used to generate the degree of unknownness un are desirably those obtained in the same detection time. For example, when the degree of unknownness un is calculated using the command speed ds to operate the motor 20 as the detection condition signal dcs, the degree of anomaly an is determined using the torque when the motor 20 is operated by the command speed ds as the detection state signal dss. Thus, it is desirable that the degree of anomaly an and the degree of unknownness un correspond to each other.

When the detection condition signal dcs used to generate the degree of unknownness un and the detection state signal dss used to generate the degree of anomaly an correspond to each other, anomaly detection can be performed with high accuracy. In addition, anomaly detection can be performed with fewer occurrences of false detection, overlooking, and the like.

Next, in step S102, when the degree of anomaly an exceeds the threshold THF1″ and the degree of unknownness un is less than or equal to the threshold THU1″, the anomaly determination unit 19 proceeds to step S103. Otherwise, the anomaly determination unit 19 proceeds to step S104. Here, a case where the degree of unknownness un is less than or equal to the threshold THU1″ is either a case where the degree of unknownness un is equal to the threshold THU1″ or a case where the degree of unknownness un is less than the threshold THU1″. Step S102 is a step in which the anomaly determination unit 19 determines whether the state is anomalous or normal.

In step S103, the anomaly determination unit 19 outputs a determination result indicating that an anomaly has occurred in the mechanical apparatus 2 as the determination result jr. In step S104, the anomaly determination unit 19 outputs a determination result indicating that the mechanical apparatus 2 is normal as the determination result jr. Steps S103 and S104 may include the operation of notifying a user of the determination result jr through an interface or the like as necessary. The above is the description of the operation flow in FIG. 12.

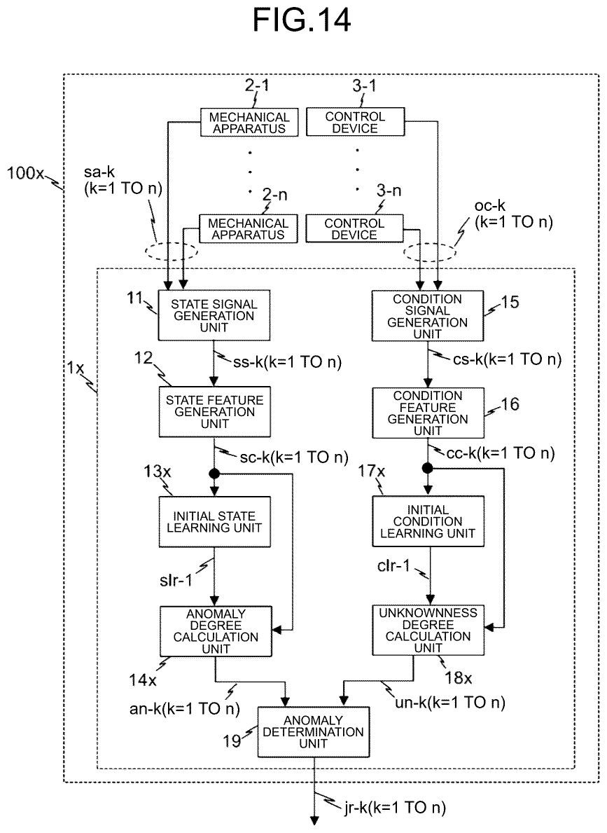

FIG. 14 is a block diagram illustrating an example of a configuration of a mechanical system 100x according to the present embodiment. A variation of the present embodiment will be illustrated with reference to FIG. 14. The following mainly describes a point of difference from the anomaly detection device 1. The mechanical system 100x includes an anomaly detection device 1x. The anomaly detection device 1x is different from the anomaly detection device 1 in that the anomaly detection device 1x uses the same learning models when monitoring a plurality of mechanical apparatuses 2-1 to 2-n. When the plurality of mechanical apparatuses 2-1 to 2-n have substantially the same characteristics, the effects of the anomaly detection device 1x of the present embodiment described with reference to FIG. 14 are exhibited more greatly.

An example of the same characteristics described above is a case where, for example, the mechanical apparatuses 2-1 to 2-n are manufactured with the same specifications and are operated under different operating conditions oc. Another example is a case where a motor is commonly used for driving the mechanical apparatuses 2-1 to 2-n, anomalies due to the movement of the motor are mainly detected, and the operating conditions oc and the state quantities sa relate to the motor or objects to be driven by the motor. The anomaly detection device 1x obtains a state signal ss-k from a mechanical apparatus 2-k (k is an integer between 1 and n). The anomaly detection device 1x obtains an operating condition oc-k from a control device 3-k.

An initial state learning unit 13x outputs initial state learning results slr-1 based on initial learning state features lsc-1. Then, an anomaly degree calculation unit 14x outputs the degree of anomaly an-k on the mechanical apparatus 2-k, based on the initial state learning results slr-1 and detection state features dsc-k.

An initial condition learning unit 17x outputs initial condition learning results clr-1 based on initial learning condition features lcc-1. Then, an unknownness degree calculation unit 18x outputs the degree of unknownness un-k on the mechanical apparatus 2-k, based on the initial condition learning results clr-1 and detection condition features dcc-k.

The anomaly determination unit 19 outputs a determination result jr-k on the mechanical apparatus 2-k, based on the degree of anomaly an-k and the degree of unknownness un-k. Since the anomaly detection device 1x uses the same learning models for the mechanical apparatus 2-k (k=1 to n), calculation load can be reduced compared with that when calculation models are prepared for each mechanical apparatus 2-k (k=1 to n). Furthermore, a large number of pieces of data at the time of the initial state learning can be prepared in parallel. The above is the description of the variation of the present embodiment illustrated in FIG. 14.

A variation of the anomaly detection device 1 of the present embodiment illustrated in FIG. 1 will be described. In the flowchart of FIG. 13, the degree of anomaly an and the degree of unknownness un are each provided with one threshold. Instead of this, the values of the degree of anomaly an and the degree of unknownness un may be provided with a plurality of thresholds to be divided into a plurality of ranges. A determination as to whether the state is anomalous or normal may be made based on a combination of a range in which the degree of anomaly an is included and a range in which the degree of unknownness un is included.

In the flowchart of FIG. 13, one of two types, anomaly and normality, is output as the determination result jr, but the anomaly determination unit 19 may be configured to output three or more types of determination results jr, according to the degree of anomaly an and the degree of unknownness un. For example, the anomaly determination unit 19 may be configured to determine the determination result jr in four levels, severe anomaly, slight anomaly, further normality that requires slight observation, and normality that does not require observation. At this time, the anomaly determination unit 19 may be configured to provide a plurality of thresholds to the degree of anomaly an or the degree of unknownness un as described above. In the flowchart of FIG. 13, anomaly detection is performed using one set of the degree of anomaly an and the degree of unknownness un, but a plurality of sets of the degree of anomaly an and the degree of unknownness un may be calculated, and a determination result of whether the state is anomalous or normal may be output on each set. Here, depending on the sets, different degrees of anomaly an may be used or the same degree of anomaly an may be used. Further, depending on the sets, different degrees of unknownness un may be used or the same degree of unknownness un may be used. Note that the modifications described above may be performed in combination with each other.

The control device of Patent Literature 1 quantitatively expresses the load conditions using a single numerical value, in other words, using a single scalar value. In the control device of Patent Literature 1, when the load conditions of a single numerical value cannot provide expression, the value of the second threshold will be inaccurate, and the result of determination is likely to suffer false detection, overlooking, or the like. Examples of a case where a change in the state of the mechanical apparatus cannot be expressed by the load conditions include a case where the state of the mechanical equipment changes complicatedly with time, and a case where the external environment changes while the load conditions of the mechanical equipment are the same. The anomaly detection device 1 of the present embodiment performs condition learning using a time-series signal. Therefore, even when a complicated change occurs between the time of generating a learning model and the time of evaluation (detection), determination can be accurately performed.

An example of the anomaly detection device 1 described in the present embodiment includes the state signal generation unit 11, the condition signal generation unit 15, the state feature generation unit 12, the condition feature generation unit 16, the initial state learning unit 13, the initial condition learning unit 17, the anomaly degree calculation unit 14, and the unknownness degree calculation unit 18.

The state signal generation unit 11 generates the state signal ss by detecting the state of the mechanical apparatus 2 in time series. The condition signal generation unit 15 generates the condition signal cs by detecting the operating condition indicating the operating status of the mechanical apparatus 2 in time series. The state feature generation unit 12 generates the state features sc based on the state signal ss. The condition feature generation unit 16 generates the condition features cc based on the condition signal cs. The initial state learning unit 13 outputs the results of learning based on the initial learning state features lsc, which are the state features sc at the time of the initial state learning, as the initial state learning results slr.

The initial condition learning unit 17 outputs the results of learning based on the initial learning condition features lcc, which are the condition features cc at the time of the initial condition learning, as the initial condition learning results clr. The anomaly degree calculation unit 14 obtains the initial state learning results slr or the additional state learning results aslr as the state learning results, and calculates the degree of anomaly an based on the state learning results and the detection state features dsc, which are the state features sc at the time of the detection. The unknownness degree calculation unit 18 obtains the initial condition learning results clr or the additional condition learning results aclr as the condition learning results, and calculates the degree of unknownness un based on the condition learning results and the detection condition features dcc, which are the condition features cc at the time of the detection. Here, it is desirable that the time of the detection of the condition features cc be the same as the time of the detection of the state features sc.

The anomaly detection device 1 of the present embodiment may include the anomaly determination unit 19. The anomaly determination unit 19 detects anomalies in the mechanical apparatus 2 based on the degree of anomaly an and the degree of unknownness un. The anomaly determination unit 19 determines that the state of the mechanical apparatus 2 is anomalous when the degree of anomaly an is greater than the predetermined first threshold and the degree of unknownness un is less than the predetermined second threshold. The anomaly determination unit 19 may determine that the state of the mechanical apparatus 2 is normal when the degree of anomaly an is less than or equal to the first threshold or the degree of unknownness un is greater than or equal to the second threshold.

The condition feature generation unit 16 may generate a plurality of statistics calculated from the condition signal cs at a plurality of time points as the condition features cc. The condition feature generation unit 16 may generate frequency characteristics of the time-series condition signal cs by frequency analysis as the condition features cc. The mechanical apparatus 2 may be driven by the motor 20 to operate. The operating condition oc may be a control signal that defines the shape of the time response of at least one of the position of the motor 20, the speed of the motor 20, the acceleration of the motor 20, the jerk of the motor 20, and the driving force of the motor 20.

An example of the mechanical system described in the present embodiment includes the mechanical apparatus 2, the state signal generation unit 11, the condition signal generation unit 15, the state feature generation unit 12, the condition feature generation unit 16, the initial state learning unit 13, the initial condition learning unit 17, the anomaly degree calculation unit 14, and the unknownness degree calculation unit 18.

The state signal generation unit 11 generates the state signal ss by detecting the state of the mechanical apparatus 2 in time series. The condition signal generation unit 15 generates the condition signal cs by detecting the operating condition indicating the operating status of the mechanical apparatus 2 in time series. The state feature generation unit 12 generates the state features sc based on the state signal ss. The condition feature generation unit 16 generates the condition features cc based on the condition signal cs. The initial state learning unit 13 outputs the results of learning based on the initial learning state features lsc, which are the state features sc at the time of the initial state learning, as the initial state learning results slr.

The initial condition learning unit 17 outputs the results of learning based on the initial learning condition features lcc, which are the condition features cc at the time of the initial condition learning, as the initial condition learning results clr. The anomaly degree calculation unit 14 obtains the initial state learning results slr or the additional state learning results aslr as the state learning results, and calculates the degree of anomaly an based on the state learning results and the detection state features dsc, which are the state features sc at the time of the detection. The unknownness degree calculation unit 18 obtains the initial condition learning results clr or the additional condition learning results aclr as the condition learning results, and calculates the degree of unknownness un based on the condition learning results and the detection condition features dcc, which are the condition features cc at the time of the detection. Here, it is desirable that the time of the detection of the condition features cc be the same as the time of the detection of the state features sc.

An example of an anomaly detection method described in the present embodiment includes a state signal generation step, a condition signal generation step, a state feature generation step, a condition feature generation step, an initial state learning step, an initial condition learning step, an anomaly degree calculation step, and an unknownness degree calculation step.

The state signal generation step generates the state signal ss by detecting the state of the mechanical apparatus 2 in time series. The condition signal generation step generates the condition signal cs by detecting the operating condition indicating the operating status of the mechanical apparatus 2 in time series. The state feature generation step generates the state features sc based on the state signal ss. The condition feature generation unit 16 generates the condition features cc based on the condition signal cs. The initial state learning step outputs the results of learning based on the initial learning state features lsc, which are the state features sc at the time of the initial state learning, as the initial state learning results slr.

The initial condition learning step outputs the results of learning based on the initial learning condition features lcc, which are the condition features cc at the time of the initial condition learning, as the initial condition learning results clr. The anomaly degree calculation step obtains the initial state learning results slr or the additional state learning results aslr as the state learning results, and calculates the degree of anomaly an based on the state learning results and the detection state features dsc, which are the state features sc at the time of the detection. The unknownness degree calculation step obtains the initial condition learning results clr or the additional condition learning results aclr as the condition learning results, and calculates the degree of unknownness un based on the condition learning results and the detection condition features dcc, which are the condition features cc at the time of the detection. Here, it is desirable that the time of the detection of the condition features cc be the same as the time of the detection of the state features sc.

Although the present embodiment has described the prevention of false detection, overlooking can also be prevented in the same manner as the prevention of false detection. In the present disclosure, the output of the determination result jr representing anomaly for the mechanical apparatus 2 in a normal state in which no anomalies have occurred is referred to as false detection. On the other hand, the output of the determination result jr representing normality for the mechanical apparatus 2 in which an anomaly has occurred is referred to as overlooking. Furthermore, even when three or more determination results are output, such as when the determination result is output in three levels, severe anomaly, slight anomaly, and normal, the output of erroneous determination results can be prevented similarly to the prevention of false detection. As described above, even when the operating condition of the mechanical apparatus 2 changes, the anomaly detection device 1 of the present embodiment can perform anomaly detection with less output of erroneous determination results such as false detection and overlooking. Furthermore, even when the operating condition of the mechanical apparatus 2 when executing the initial state learning is different from the operating condition of the mechanical apparatus 2 under anomaly detection, the anomaly detection device 1 can prevent the occurrence of output of an erroneous determination result such as false detection or overlooking. In the embodiment described in the present embodiment, even when the initial learning condition signal lcs is different from the detection condition signal dcs, the occurrence of output of an erroneous determination result such as false detection or overlooking can be prevented. Here, the operating condition is the operating condition oc in the present embodiment. Here, the output of an erroneous determination result in the present disclosure includes not only erroneous display to the operator, erroneous output of a signal indicating a determination result, and the like, but also an erroneous change in the operating state of the mechanical apparatus 2.

Even for the mechanical apparatus 2 whose operating conditions change complicatedly in the system to detect anomalies occurring in the mechanical apparatus 2, the anomaly detection device in the present embodiment can prevent the output of erroneous determination results such as false detection and overlooking.

### Second Embodiment

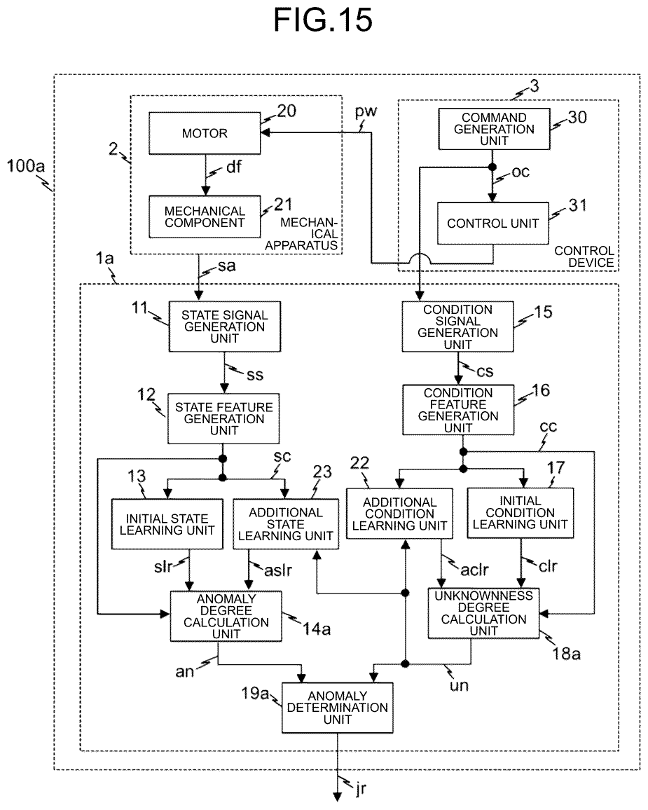

FIG. 15 is a block diagram illustrating an example of a configuration of a mechanical system 100a according to the present embodiment. The mechanical system 100a includes an anomaly detection device 1a instead of the anomaly detection device 1 of the first embodiment. The anomaly detection device 1a includes an additional condition learning unit 22 and an additional state learning unit 23 in addition to the components of the anomaly detection device 1. The anomaly detection device 1a includes an unknownness degree calculation unit 18a instead of the unknownness degree calculation unit 18. The anomaly detection device 1a includes an anomaly degree calculation unit 14a instead of the anomaly degree calculation unit 14. The anomaly detection device 1a includes an anomaly determination unit 19a instead of the anomaly determination unit 19. In these points, the anomaly detection device 1a is different from the anomaly detection device 1. In FIG. 15, components identical to or corresponding to those in FIG. 1 of the first embodiment are denoted by the same reference numerals.

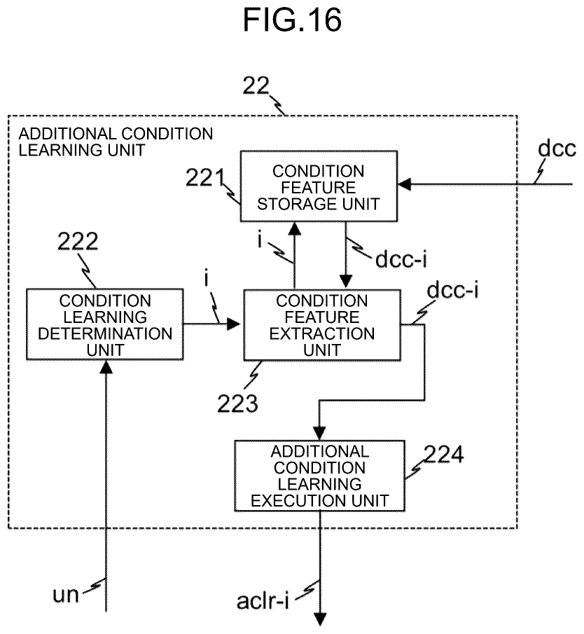

FIG. 16 is a block diagram illustrating an example of a configuration of the additional condition learning unit 22 according to the present embodiment. The additional condition learning unit 22 includes a condition feature storage unit 221 that stores the condition features cc, and a condition learning determination unit 222 that determines whether or not to execute additional condition learning that is added condition learning. The additional condition learning unit 22 includes a condition feature extraction unit 223 that extracts the condition features cc, and an additional condition learning execution unit 224 that executes the additional condition learning. The additional condition learning execution unit 224 executes the additional condition learning on the detection condition features dcc extracted by the condition feature extraction unit 223.

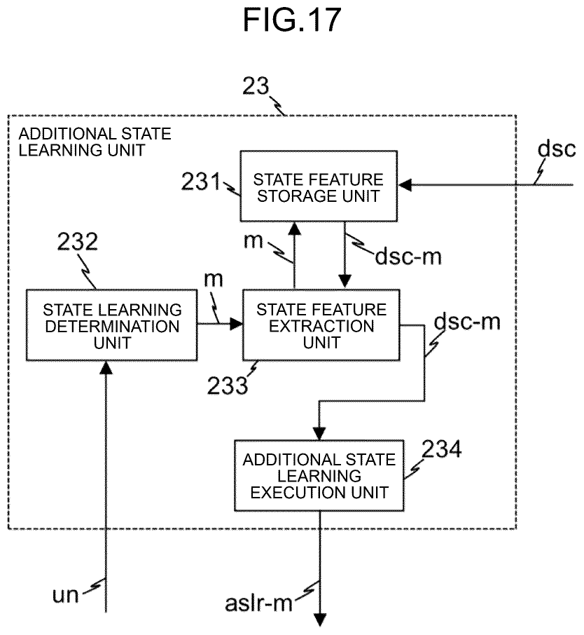

FIG. 17 is a block diagram illustrating an example of a configuration of the additional state learning unit 23 according to the present embodiment. The additional state learning unit 23 includes a state feature storage unit 231 that stores the state features sc, and a state learning determination unit 232 that determines whether or not to execute additional state learning that is added state learning for each degree of unknownness un. The additional state learning unit 23 includes a state feature extraction unit 233 that extracts the state features sc, and an additional state learning execution unit 234 that executes the additional state learning. The additional state learning execution unit 234 executes the additional state learning on the detection state features dsc extracted by the state feature extraction unit 233.

An embodiment of each component of the additional condition learning unit 22 illustrated in FIG. 16 will be illustrated. The condition feature storage unit 221 stores the detection condition features dcc for a certain period of time. Here, a plurality of sets of detection condition features dcc is output in time series. The unknownness degree calculation unit 18a outputs a plurality of degrees of unknownness un in time series, based on the initial condition learning results clr and each of the plurality of sets of detection condition features dcc output in time series. The condition learning determination unit 222 determines whether or not to execute the additional condition learning for each of the plurality of degrees of unknownness un. For example, the condition learning determination unit 222 may compare each degree of unknownness un obtained with a predetermined threshold (third threshold).

The operation of the condition learning determination unit 222 will be illustrated. One of the plurality of degrees of unknownness un is referred to as the degree of unknownness un-i (i is an integer greater than or equal to 1). One of the plurality of degrees of unknownness un that is different from the degree of unknownness un-i is referred to as the degree of unknownness un-j (j is an integer different from i and greater than or equal to 1). Here, i and j are arguments of the degree of unknownness un-i and the degree of unknownness un-j, respectively. Assume that as a result of comparison, the degree of unknownness un-i is less than or equal to the third threshold, and the degree of unknownness un-j is greater than the third threshold. In this case, the condition learning determination unit 222 outputs the argument i and does not output the argument j. The above is an example of the operation of the condition learning determination unit 222.

The condition feature extraction unit 223 obtains the argument i output by the condition learning determination unit 222. Then, the condition feature extraction unit 223 extracts detection condition features dcc-i corresponding to the obtained argument i from the plurality of sets of detection condition features dcc stored in the condition feature storage unit 221. The additional condition learning execution unit 224 executes condition learning based on the extracted detection condition features dcc-i. This condition learning is referred to as additional condition learning. The initial condition learning described in the first embodiment and the additional condition learning are included in the condition learning. In other words, the initial condition learning and the additional condition learning are each a form of the condition learning.

The form of the additional condition learning executed by the additional condition learning execution unit 224 may be the same as the form of the initial condition learning described in the first embodiment except that the condition learning is executed based on the detection condition features dcc instead of the initial learning condition features lcc. The modifications of the initial condition learning described in the first embodiment are also applicable to the additional condition learning. The additional condition learning, which may be executed either in the same form as the initial condition learning or in a different form, is desirably executed in the same form. When the additional condition learning is in the same form as the initial condition learning, the degree of unknownness un after the additional condition learning is calculated in the same manner as the degree of unknownness un before the additional condition learning, so that consistency can be provided to determination performed by the anomaly determination unit 19a. The determination performed by the anomaly determination unit 19a described above is determination for anomaly detection based on the degree of anomaly an and the degree of unknownness un. Here, the results of the additional condition learning are referred to as additional condition learning results alcr. As described above, the initial condition learning results clr and the additional condition learning results alcr are included in the condition learning results. In the example of FIG. 16, the additional condition learning execution unit 224 outputs additional condition learning results alcr-i corresponding to the argument i. The above is the description of the components of the additional condition learning unit 22 illustrated in FIG. 16.

Furthermore, processing after the additional condition learning execution unit 224 outputs the additional condition learning results alcr will be described. As illustrated in FIG. 15, the unknownness degree calculation unit 18a updates the condition learning results from the initial condition learning results clr to the additional condition learning results alcr. Then, the unknownness degree calculation unit 18a calculates the degree of unknownness un based on the additional condition learning results alcr, which are the updated condition learning results, and the detection condition features dcc obtained after the update. In the example of FIG. 15, the method of calculating the degree of unknownness un by the unknownness degree calculation unit 18a is described as being the same before and after the obtainment of the added condition learning results alcr except that the additional condition learning results alcr are used instead of the initial condition learning results clr. The method of calculating the degree of unknownness un may be changed before and after the obtainment of the additional condition learning results alcr. The operation of the anomaly determination unit 19a will be described later after the description of the additional state learning unit 23.

In the example of FIG. 16, the argument i is provided to the degree of unknownness un-i to associate the degree of unknownness un with the condition features cc (in this case, the detection condition features dcc). However, something different from the argument may be used to associate the degree of unknownness un with the condition features cc. For example, a sign, a symbol, or the like different from the argument i that can be attached to the data may be used for association. Alternatively, for example, instead of the argument, a set of data corresponding to each other such as the condition signal cs, the condition features cc, and the degree of unknownness un may be assigned the same number to be associated with each another. The condition features cc used to calculate the degree of unknownness un-i is referred to as condition features cc-i, and the operating condition oc used to obtain the condition features cc-i is referred to as an operating condition oc-i. In this case, instead of the argument i, the time at which the operating condition oc-i has been obtained may be attached to the degree of unknownness un and the condition features cc for association.

Next, a form of the additional state learning unit 23 illustrated in FIG. 17 will be illustrated. The additional state learning unit 23 includes the state feature storage unit 231, the state learning determination unit 232, the state feature extraction unit 233, and the additional state learning execution unit 234. The state feature storage unit 231 stores the detection state features dsc for a certain period of time. Here, in the example of FIG. 17, a plurality of sets of detection state features dsc is output in time series. Meanwhile, the unknownness degree calculation unit 18a outputs a plurality of degrees of unknownness un in time series, based on the initial condition learning results clr and each of the plurality of sets of detection condition features dcc output in time series. The state learning determination unit 232 determines whether or not to execute the additional state learning for each of the plurality of degrees of unknownness un output from the unknownness degree calculation unit 18a.

The operation of the state learning determination unit 232 will be illustrated. For example, the state learning determination unit 232 may compare the degree of unknownness un obtained with a predetermined threshold (fourth threshold). One of the plurality of degrees of unknownness un is referred to as the degree of unknownness un-m (m is an integer greater than or equal to 1). One of the plurality of degrees of unknownness un that is different from the degree of unknownness un-m is referred to as the degree of unknownness un-n (n is an integer different from m and greater than or equal to 1). Here, m and n are arguments of the degree of unknownness un-m and the degree of unknownness un-n, respectively. Assume that as a result of comparison, the degree of unknownness un-m is less than or equal to the fourth threshold, and the degree of unknownness un-n is greater than the fourth threshold. In this case, the condition learning determination unit 222 outputs the argument m and does not output the argument n. The above is an example of the operation of the state learning determination unit 232.

The state feature extraction unit 233 extracts detection state features dsc-m corresponding to the argument (the argument m in the example of FIG. 17) output by the state learning determination unit 232 from the plurality of sets of detection state features dsc stored in the state feature storage unit 231. The additional state learning execution unit 234 executes state learning based on the extracted detection state features dsc-m. This state learning is referred to as additional state learning. As described above, the initial state learning described in the first embodiment and the additional state learning described in the present embodiment are included in the state learning. In other words, the initial state learning and the additional state learning are each a form of the state learning.

As illustrated in FIG. 17, the form of the additional state learning may be the same as the form of the initial state learning described in the first embodiment except that the state learning is executed based on the detection state features dsc instead of the initial learning state features lsc. The additional state learning, which may be executed either in the same form as the initial state learning or in a different form, is desirably executed in the same form. When the additional state learning is in the same form as the initial state learning, the degree of anomaly an after the additional state learning is calculated in the same manner as the degree of anomaly an before the additional state learning, so that consistency can be provided to determination performed by the anomaly determination unit 19a. The determination performed by the anomaly determination unit 19a described above is determination for anomaly detection based on the degree of anomaly an and the degree of unknownness un. Note that the modifications of the initial state learning described in the first embodiment are also applicable to the additional state learning.

Here, the results of the additional state learning are referred to as the additional state learning results aslr. The initial state learning results slr and the additional state learning results aslr are included in the state learning results. In the example of FIG. 17, the additional state learning execution unit 234 outputs additional state learning results aslr-m corresponding to the argument m. The above is the description of the components of the additional state learning unit 23 illustrated in FIG. 17.

Furthermore, processing on the output additional state learning results aslr will be illustrated. As illustrated in FIG. 15, the anomaly degree calculation unit 14a updates the state learning results held from the initial state learning results slr to the additional state learning results aslr. Then, the anomaly degree calculation unit 14a outputs the degree of anomaly an based on the additional state learning results aslr, which are the updated state learning results, and the detection state features dsc obtained after the update. Here, before and after the update of the state learning results, the method of calculating the degree of anomaly an by the anomaly degree calculation unit 14a may be the same or different. When the method of calculating the degree of anomaly an is the same before and after the update, consistency can be provided to the degree of anomaly an.

Furthermore, the anomaly determination unit 19a outputs the determination result jr based on the degree of anomaly an and the degree of unknownness un, similarly to the anomaly determination unit 19 described in the first embodiment. Here, the degree of anomaly an and the degree of unknownness un obtained by the anomaly determination unit 19a are those output after the unknownness degree calculation unit 18a updates the condition learning results, and the anomaly degree calculation unit 14a updates the state learning results. As described above, the anomaly detection device 1a of the present embodiment executes the additional condition learning in addition to the initial condition learning, and executes the additional state learning in addition to the initial state learning.

Here, the condition learning determination unit 222 may further use the degree of unknownness un calculated using the additional condition learning results aclr to determine whether or not to execute the additional condition learning to update the condition learning results. The state learning determination unit 232 may further use the degree of unknownness un calculated using the additional state learning results aslr to determine whether or not to execute the additional state learning to update the state learning results as appropriate. Note that in the additional state learning unit 23, the degree of unknownness un and the state features sc may be associated with each other by something other than the argument, as is the case with the association between the degree of unknownness un and the condition features cc in the additional condition learning unit 22.

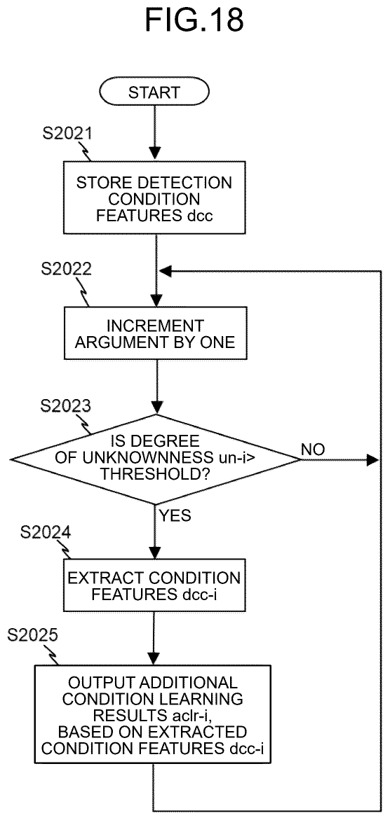

FIG. 18 is a flowchart illustrating an example of operation of the additional condition learning unit 22. As a premise, during the initial learning time before START in FIG. 18, the initial condition learning unit 17 has already output the initial condition learning results clr based on the initial learning condition features lcc. Then, the unknownness degree calculation unit 18a includes the initial condition learning results clr.

The following describes the operation in the detection time. At this time, the anomaly detection device 1a is performing anomaly detection. The condition feature generation unit 16 generates the detection condition features dcc based on the operating condition oc in the detection time. Since the detection condition features dcc are included in the condition features cc, the symbol of the condition features cc is illustrated in FIG. 15.

In step S2021, the condition feature storage unit 221 stores the detection condition features dcc. In step S2022, the condition learning determination unit 222 increments the argument by one. For example, the argument is sequentially attached over time to the detection condition features dcc obtained in time series. The argument may be updated from an argument i−1 to the argument i described in FIG. 16. In step S2023, the condition learning determination unit 222 determines whether or not the degree of unknownness un-i is greater than the third threshold described in FIG. 16. This threshold may be the same as or different from a threshold for the anomaly determination unit 19a to determine whether it is appropriate to determine whether the state is normal or anomalous based on the degree of anomaly an. The threshold for the anomaly determination unit 19a to determine whether it is appropriate to determine whether the state is normal or anomalous based on the degree of anomaly an is, for example, a value such as the threshold THU1″ described in the operation example in FIG. 12 of the first embodiment. It is preferable to set this threshold to the same value as that when the anomaly determination unit 19a determines whether the state is normal or anomalous based on the degree of anomaly an, because when it is inappropriate that the anomaly determination unit 19a determines whether the state is normal or anomalous, the additional condition learning is executed.

When the degree of unknownness un-i is less than or equal to the threshold, the additional condition learning unit 22 determines that there is no need to perform the additional condition learning for the degree of unknownness un-i with the argument i, and proceeds to step S2022. In this case, the additional condition learning is not executed for the argument i, and the condition learning results held by the unknownness degree calculation unit 18a are maintained without being updated. Then, the calculation of the degree of unknownness un continues based on the condition learning results held by the unknownness degree calculation unit 18a and the detection condition features dcc. In this case, the argument is incremented again in step S2022, and the condition learning determination unit 222 determines whether or not to execute the additional condition learning for the degree of unknownness un with the updated argument i+1.

If the degree of unknownness un-i is greater than the threshold in step S2023, the process proceeds to step S2024. In step S2024, the condition feature extraction unit 223 obtains the argument i and extracts the condition features cc corresponding to the argument i, in other words, the detection condition features dcc-i from the condition feature storage unit 221. Then, the additional condition learning unit 22 proceeds to step S2025. In step S2025, the additional condition learning execution unit 224 outputs the additional condition learning results aclr-i based on the detection condition features dcc-i extracted by the condition feature extraction unit 223.

When the process proceeds to step S2025, the unknownness degree calculation unit 18a updates the condition learning results held previously to the additional condition learning results aclr-i. The above is the operation flow of the additional condition learning unit 22 illustrated in FIG. 18. After the condition learning results have been updated, the unknownness degree calculation unit 18a calculates the degree of unknownness un based on the updated condition learning results and the detection condition features dcc obtained after the update. This processing of the unknownness degree calculation unit 18a is performed on each set of detection condition features dcc generated in the condition feature generation unit 16 until the condition learning results are updated next.

In the example illustrated in FIG. 18, the additional condition learning execution unit 224 outputs the additional condition learning results aclr-i based on the detection condition features dcc-i. However, the present embodiment is not limited to this form. The number of the detection condition features dcc used in the additional condition learning and the argument of the detection condition features dcc can be freely selected. For example, a plurality of pieces of data obtained after the detection condition features dcc-i may be selected. As an example, 100 pieces of data from detection condition features dcc-i+1 to detection condition features dcc-i+100 are extracted. Then, the additional condition learning results aclr-i may be output based on the extracted 100 pieces of data. While extracting the data, the condition learning determination unit 222 may determine not to update the condition learning results.

Furthermore, for example, in FIG. 18, the condition feature storage unit 221 or the like stores the initial learning condition features lcc used in the initial condition learning. Then, in step S2025 of FIG. 18, the additional condition learning execution unit 224 may execute the additional condition learning based on the stored initial learning condition features lcc and the detection condition features dcc-i obtained after that. By using the initial learning condition features lcc as part of training data for the additional condition learning, even when the quantity of the detection condition features dcc obtained is not sufficient, the additional condition learning execution unit 224 can compensate for the shortage of data to execute learning.

Instead of the condition learning determination unit 222, the anomaly determination unit 19a may determine whether or not to execute the additional condition learning. In other words, when the anomaly determination unit 19a determines that the degree of unknownness un is greater than the threshold, the additional condition learning unit 22 may execute the additional condition learning. In this form, when the anomaly determination unit 19a determines that it is an unknown status in which it is inappropriate to determine whether the state is normal or anomalous, the additional condition learning is executed, so that anomaly detection can be efficiently performed. Furthermore, this form can omit the condition learning determination unit 222.

The condition learning determination unit 222 only needs to determine whether or not to execute the additional condition learning, based on the degree of unknownness un for which the additional condition learning is executed. The method is not limited to the method described with reference to FIG. 18. For example, a threshold is set for the degree of unknownness un. Determination as to whether or not the degree of unknownness un exceeds the threshold is performed on each of a plurality of uns obtained in time series. When the degree of unknownness un exceeds the threshold continuously for a predetermined number of times, it may be determined that the additional condition learning be executed. The additional condition learning execution unit 224 may obtain a plurality of sets of detection condition features dcc corresponding to the degrees of unknownness un exceeding the threshold, and execute the additional condition learning based on the obtained plurality of sets of detection condition features dcc. When the determination as to whether or not to execute the additional condition learning is performed with this form, it can be determined whether or not it is necessary to execute the additional condition learning, based on the values of a plurality of degrees of unknownness un consecutive in time series. Thus, there is an advantage that erroneous determination as to whether or not it is necessary to execute the additional condition learning is unlikely to occur.

As described above, when the unknown operating condition oc, the detection condition features dcc, etc. are calculated by executing the additional condition learning, the anomaly detection device 1a obtains information such as the unknown operating condition oc, the detection condition features dcc, etc. Then, anomaly detection appropriate to the unknown operating condition oc, the detection condition features dcc, etc. can be performed. Consequently, anomaly detection with less output of erroneous determination results such as false detection and overlooking can be performed on various operating conditions oc and various detection condition features dcc.

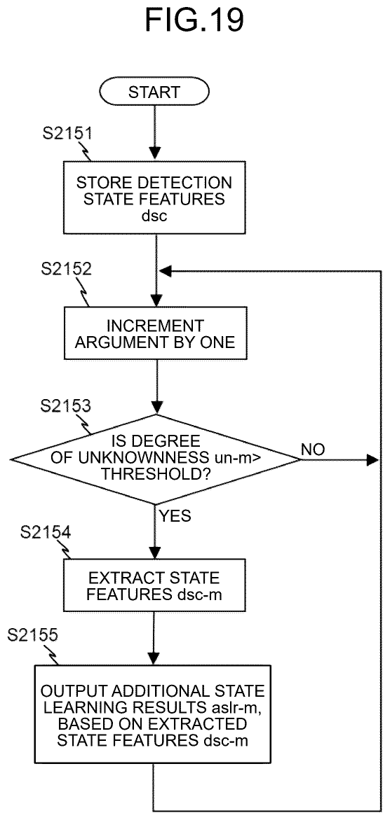

FIG. 19 is a flowchart illustrating an example of operation of the additional state learning unit 23 according to the present embodiment. As a premise, during the initial learning time before START in FIG. 19, the initial state learning unit 13 has already output the initial state learning results slr based on the initial learning state features lsc. Then, the anomaly degree calculation unit 14a includes the initial state learning results slr.

The following describes the operation in the detection time after the initial learning time. At this time, the anomaly detection device 1a is performing anomaly detection. The state feature generation unit 12 generates the detection state features dsc based on the state quantity sa in the detection time. Since the detection state features dsc are included in the state features sc, the symbol of the state features sc is illustrated in FIG. 15.

In step S2151, the state feature storage unit 231 stores the detection state features dsc. In step S2152, for example, the state learning determination unit 232 increments the argument by one. For example, the argument is sequentially attached over time to the detection state features dsc obtained in time series. This argument may be updated from an argument m−1 to the argument m described in FIG. 17. In step S2153, the state learning determination unit 232 determines whether or not the degree of unknownness un-m is greater than a predetermined threshold. This threshold may be the same as or different from the threshold used by the anomaly determination unit 19a when determining whether the state is anomalous or normal, based on the degree of anomaly an. It is preferable to set this threshold for the state learning determination unit 232 to the same value as the threshold used to determine whether the state is anomalous or normal based on the degree of anomaly an, because when it is inappropriate for the anomaly determination unit 19a to determine whether the state is normal or anomalous, the additional state learning is executed. The threshold for the state learning determination unit 232 may be the same as or different from the threshold for the condition learning determination unit 222. When the thresholds are the same, one of the condition learning determination unit 222 and the state learning determination unit 232 can be omitted. In addition, the calculation load can be reduced. Furthermore, since the additional state learning is also executed when the additional condition learning is executed, the state learning results and the condition learning results are simultaneously updated. In this case, the anomaly degree calculation unit 14a uses the updated state learning results matching the updated condition learning results used in the unknownness degree calculation unit 18a, so that anomaly detection with higher accuracy can be performed.

When the degree of unknownness un-m is less than or equal to the predetermined threshold, the additional state learning unit 23 determines that there is no need to perform the additional state learning for the degree of unknownness un-m with the argument m, and proceeds to step S2152. In this case, the additional state learning is not executed for the argument m, and the state learning results used by the anomaly degree calculation unit 14a are maintained without being updated. Then, the calculation of the degree of anomaly an continues based on the state learning results held by the anomaly degree calculation unit 14a and the detection state features dsc. In step S2152, the argument is updated again from m to m+1, and the state learning determination unit 232 determines whether or not to execute the additional state learning for the next argument m+1.

In step S2153, if the degree of unknownness un-m is greater than the threshold, the additional state learning unit 23 proceeds to step S2154. In step S2154, the state feature extraction unit 233 obtains the argument m and extracts the state features sc corresponding to the argument m, in other words, the detection state features dsc-m from the state feature storage unit 231. Then, the additional state learning unit 23 proceeds to step S2155. In step S2155, the additional state learning execution unit 234 outputs the additional state learning results aslr-m based on the detection state features dsc-m extracted by the state feature extraction unit 233. The above is the operation flow of the additional state learning unit 23 illustrated in FIG. 19.

When the process proceeds to step S2155, the anomaly degree calculation unit 14a updates the state learning results held previously to the additional state learning results aslr-m. After the state learning results have been updated, the anomaly degree calculation unit 14a calculates the degree of anomaly an based on the updated state learning results and the detection state features dsc obtained after the update. The processing of the anomaly degree calculation unit 14a to calculate the degree of anomaly an based on the updated state learning results and the detection state features dsc obtained after the update is performed on each set of detection state features dsc generated in the state feature generation unit 12 until the state learning results are updated next.

Note that in the example illustrated in FIG. 19, the additional state learning execution unit 234 outputs the additional state learning results aslr-m, based on the detection state features dsc-m, but is not limited to this form. The state features sc to be used in the additional state learning can be freely selected. For example, 100 sets of detection condition features dcc generated after the detection state features dsc-m, such as from the detection state features dsc-m+1 to the detection state features dsc-m+100, may be used in the additional state learning. Based on these, the additional state learning results aslr-m may be output.

When the additional state learning unit 23 is configured to execute the additional state learning for the degree of unknownness un for which the additional condition learning unit 22 has performed the additional condition learning, not only the condition learning results held by the unknownness degree calculation unit 18a but also the state learning results held by the anomaly degree calculation unit 14a can be updated. Consequently, more accurate anomaly detection can be achieved. Anomaly detection or the like with much less output of erroneous determination results such as false detection and overlooking can be achieved. Note that only the additional condition learning by the additional condition learning unit 22 may be executed, and the update of the state learning results in the anomaly degree calculation unit 14a may not be performed. In other words, the additional state learning unit 23 may be omitted, and the anomaly degree calculation unit 14a may hold the configuration to calculate the degree of anomaly an based on the initial state learning results slr and the detection state features dsc. Even in this configuration, the condition learning results are updated when the operating condition oc is determined to be unknown. Consequently, anomaly detection with less output of erroneous determination results such as false detection and overlooking can be performed as compared with the configuration not including the additional condition learning unit 22, for example, the anomaly detection device 1 described in the first embodiment.

Next, to explain the effects of the additional condition learning, a comparison is made between the configuration in which the additional state learning unit 23 is omitted from the anomaly detection device 1a and the configuration in which the additional state learning unit 23 and the additional condition learning unit 22 are omitted from the anomaly detection device 1a. In the following description, the configuration and operation of the anomaly detection device 1 of the first embodiment described with reference to FIG. 1 will be described as an example of the configuration in which the additional state learning unit 23 and the additional condition learning unit 22 are omitted from the anomaly detection device 1a.

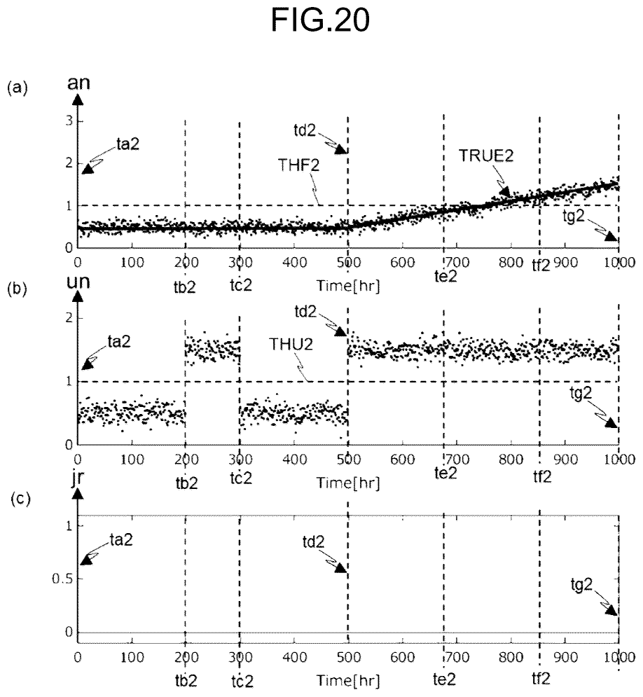

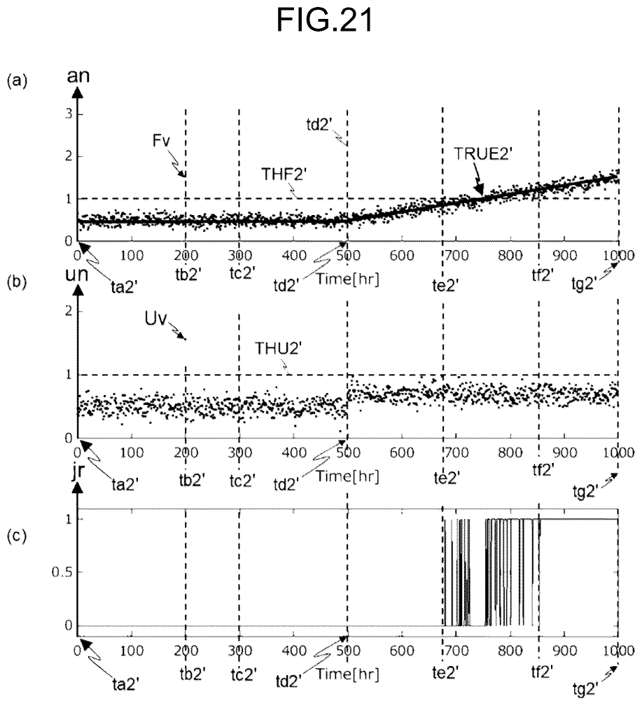

FIG. 20 is a diagram illustrating an example of temporal changes in the degree of anomaly an, the degree of unknownness un, and the determination result jr generated by the configuration in which the additional condition learning unit 22 and the additional state learning unit 23 are omitted from the anomaly detection device 1a according to the present embodiment. FIG. 20 illustrates the results of detection by the anomaly detection device 1 described in the first embodiment as an example of the configuration not including the additional condition learning unit 22 and the additional state learning unit 23. FIG. 21 is a diagram illustrating an example of temporal changes in the degree of anomaly an, the degree of unknownness un, and the determination result jr generated by the configuration in which the additional state learning unit 23 is omitted from the anomaly detection device 1a according to the present embodiment. FIG. 21 represents the results of detecting the state of the mechanical apparatus 2 by the configuration in which the additional state learning unit 23 is omitted from the anomaly detection device 1a. The following makes a comparison between FIGS. 20 and 21.

For the state of the mechanical apparatus 2 when the data illustrated in FIG. 20 is obtained, no deterioration occurs in the mechanical apparatus 2 until time td2, and the mechanical apparatus 2 gradually deteriorates from time td2 forward. Between time tb2 and time tc2 and between time td2 and time tg2, the speed of the motor is changed to settings different from those at the time of the initial learning. In the period from time ta2 to time tb2 and the period from time tc2 to time td2, the operating condition oc, that is, the speed of the motor is the same as that at the time of the initial learning.

FIGS. 20(a) and 21(a) illustrate temporal changes in the degree of anomaly an. Data points of the degree of anomaly an are plotted hourly. FIGS. 20(b) and 21(b) illustrate temporal changes in the degree of unknownness un. FIGS. 20(c) and 21(c) illustrate temporal changes in the determination result jr. In FIGS. 20 and 21, the horizontal axes represent time in hours (hr). On the time axes of FIGS. 20(a) to 20(c), positions denoted by the same reference numerals indicate the same times. On the time axes of FIGS. 21(a) to 21(c), positions denoted by the same reference numerals indicate the same times.

The example of FIG. 20 illustrates data from time ta2, which is the time when time ta2 has elapsed since the start of the operation of each anomaly detection device, to time tg2. In the example illustrated in FIG. 20, the initial condition learning and the initial state learning have been executed between the start time of the operation of each anomaly detection device and time ta2 at which the detection time is started.

In FIG. 20(a), between time ta2 and time td2, the degree of anomaly an includes some variation but all are plotted between zero and one, and the changes are mostly small. In FIG. 20(a), from time td2 to time tg2, the degree of anomaly an gradually increases as the operating time elapses. In FIG. 20(a), a threshold THF2 for the degree of anomaly an is set to one. The threshold THF2 may be determined from the distribution of the degree of anomaly an or the like when the mechanical apparatus 2 is normal. Further, in FIG. 20(a), to facilitate understanding, the true degree of anomaly TRUE2 of the mechanical apparatus 2 is indicated by a solid line. The description of the true degree of anomaly TRUE2 is the same as the description of the true degree of anomaly TRUE1 described in FIG. 10, and thus is omitted.

In FIG. 20(b), between time ta2 and time tb2 and between time tc2 and time td2, all the degrees of unknownness un are plotted between zero and one. In contrast, between time tb2 and time tc2 and between time td2 and time tg2, all the degrees of unknownness un are plotted in the range between one and two. In FIG. 20(b), a threshold THU2, which is a threshold for the degree of unknownness un, is set to one. The determination result jr in FIG. 20(c) is plotted with hourly data points connected by a line. When the mechanical apparatus 2 is normal, the determination result jr indicates a value of zero. When the mechanical apparatus 2 is anomalous, the determination result jr indicates a value of one. The form of the output of the determination result jr is not limited to this form.

In the example of FIG. 20, the anomaly determination unit 19 outputs the determination result jr as in the description of FIG. 12 of the first embodiment. Therefore, as illustrated in FIG. 20(b), all the time from time ta2 to time tg2, the determination result jr is a value of zero indicating normality since the degree of anomaly an is less than or equal to one. In contrast, the true degree of anomaly TRUE2 gradually increases at times after time td2 in FIG. 20(a).

Thus, according to the determination result jr in FIG. 20, that is, the determination result jr of the anomaly detection device 1, overlooking has occurred in which the mechanical apparatus 2 in an anomalous state is determined to be in a normal state. The occurrence of the overlooking is due to the fact that the operating condition oc different from the operating condition oc at the time of the initial learning is applied to the mechanical apparatus 2 from time td2 forward. In other words, the overlooking has occurred due to the difference between the detection condition signal dcs and the initial learning condition signal lcs.

Next, an example of FIG. 21 will be described. The example of FIG. 21 illustrates data from time ta2′, which is the time when time ta2′ has elapsed since the start of the operation of the anomaly detection device, to time tg2′. In the example illustrated in FIG. 21, the initial condition learning and the initial state learning have been executed between the start time of the operation of each anomaly detection device and time ta2′ at which the detection time is started. In FIG. 21, the mechanical apparatus 2 gradually deteriorates from time td2′ forward. In FIG. 21, in the period from time tb2′ to time tc2′ and the period from time td2′ to time tg2′, the motor speed is changed to settings different from those at the time of the initial learning. That is, the operating condition oc at the time of the detection is changed from the operating condition oc at the time of the initial learning. In the period from time ta2′ to time tb2′ and the period from time tc2′ to time td2′, the motor speed is set the same as that at the time of the initial learning. That is, the operating condition oc is set the same as the operating condition oc at the time of the initial learning.

In FIG. 21(a), time ta2′ is the time when time ta2′ has elapsed since the start of the operation of the anomaly detection device 1a. Time tg2′ is the time when time tg2′ has elapsed since the start of the operation of the anomaly detection device 1a. Note that the initial state learning and the initial condition learning when the mechanical apparatus 2 is normal have been completed at a time before time ta2′. In FIG. 21(a), data points of the degree of anomaly an are plotted hourly.

In FIG. 21(a), between time ta2′ and time tb2′ and between time tb2′ and time td2′, the value of the degree of anomaly an is plotted between zero and one. In contrast, in FIG. 21(a), the degree of anomaly an is plotted at a value Fv at the time point of time tb2′. The value Fv is a value above one. In FIG. 21(a), between time td2′ and time tg2′, the degree of anomaly an increases as the operating time elapses.

In FIG. 21(a), a threshold THF2′ for the degree of anomaly an is set to one. The threshold THF2′ is a predetermined threshold. The threshold THF2′ may be determined from the distribution of the degree of anomaly an or the like when the mechanical apparatus 2 is in a normal state. In FIG. 21(a), in addition to the degree of anomaly an estimated by the anomaly detection device 1a, the true degree of anomaly TRUE2′ of the mechanical apparatus 2 that is not affected by disturbances such as the operating condition oc is indicated by a thick line. The description of the true degree of anomaly TRUE2′ is the same as the description of the true degree of anomaly TRUE1 described in FIG. 10 of the first embodiment, and thus is omitted.

In FIG. 21(b), in the periods between time ta2′ and time tb2′ and between time tb2′ and time td2′, the degree of unknownness un is plotted between zero and one. In contrast, at the time point of time tb2′, the degree of unknownness un is plotted at a position Uv. The position Uv indicates that the value of the degree of unknownness un is a value above one at time tb2′.

In the example of FIG. 21, the additional condition learning unit 22 executes the additional condition learning at the time point of time tb2′. Consequently, an increase in the degree of unknownness un is prevented in the period after time tb2′. In contrast, in the example of FIG. 20, the additional condition learning unit 22 is omitted, and the condition learning results are not updated. Consequently, the degree of unknownness un based on the initial condition learning results clr is continuously output in the period after time tb2. Therefore, in the periods between time tb2 and time tc2 and between time td2 and time tg2, the degree of unknownness un has values greater than one.

As illustrated in FIG. 21(b), as a result of preventing an increase in the degree of unknownness un in the period after time tb2′, the determination result jr in FIG. 21(c) is different from that in FIG. 20(c), and an increase in the degree of anomaly an of the mechanical apparatus 2 can be correctly detected as an anomaly.

As described above, the anomaly detection device 1a determines whether or not the additional condition learning is necessary, based on the degree of unknownness un. When necessary, the condition learning results can be updated. Consequently, even when the operating condition oc has changed, the update of the condition learning results enables anomaly detection to be performed with less false detection and overlooking. The anomaly detection device 1a determines whether or not the additional state learning is necessary, based on the degree of unknownness un. When necessary, the state learning results can be updated. Consequently, even when the state quantity sa has changed with a change in the operating condition oc, the update of the state learning results enables anomaly detection to be performed with less false detection and overlooking. These configurations allow the anomaly detection device 1a to prevent false detection and overlooking even when the operating condition oc of the mechanical apparatus 2 changes. The anomaly detection device 1a determines whether or not to execute the additional condition learning, the additional state learning, etc., based on the time-series detection condition signal dcs. Consequently, even when the operating condition oc changes complicatedly depending on time, the anomaly detection device 1a can accurately determine whether or not it is necessary to execute the additional condition learning, the additional state learning, etc. When executing the additional condition learning or the additional state learning, using the time-series detection condition signal dcs, the anomaly detection device 1a can accurately calculate the degree of unknownness un, the degree of anomaly an, etc. even when the operating condition oc changes complicatedly depending on time. Consequently, the anomaly detection device 1a can detect anomalies with high accuracy while preventing output of erroneous determination results such as false detection and overlooking. The present embodiment, which has described the prevention of false detection and overlooking, is not limited to this. For example, as in the first embodiment, even when three or more determination results are output, such as when the determination result is output in three levels, severe anomaly, slight anomaly, and normal, the output of erroneous determination results can be prevented.

The anomaly detection device 1a of the present embodiment may further include the additional condition learning unit 22 in addition to the components of the anomaly detection device 1 described in the first embodiment. The additional condition learning unit 22 includes the condition feature storage unit 221, the condition learning determination unit 222, the condition feature extraction unit 223, and the additional condition learning execution unit 224.

The condition feature storage unit 221 stores the detection condition features dcc. The condition learning determination unit 222 determines whether or not to execute the additional condition learning based on the degree of unknownness un. The condition feature extraction unit 223 extracts the detection condition features dcc to be used in the additional condition learning from the condition feature storage unit 221 when the condition learning determination unit 222 determines to execute the additional condition learning. The additional condition learning execution unit 224 outputs the results of the execution of the additional condition learning based on the extracted detection condition features dcc as the additional condition learning results aclr.

The anomaly detection method of the present embodiment may further include an additional condition learning step in addition to the steps of the anomaly detection method described in the first embodiment. The additional condition learning step includes a condition feature storage step, a condition learning determination step, a condition feature extraction step, and an additional condition learning execution step.

The condition feature storage step stores the detection condition features dcc. The condition learning determination step determines whether or not to execute the additional condition learning based on the degree of unknownness un. When the condition learning determination step determines to execute the additional condition learning, the condition feature extraction step extracts the detection condition features dcc to be used in the additional condition learning from the detection condition features dcc stored in the condition feature storage step. The additional condition learning execution step outputs the results of the execution of the additional condition learning based on the extracted detection condition features dcc as the additional condition learning results aclr.

When the additional condition learning execution unit 224 outputs the additional condition learning results aclr, the unknownness degree calculation unit 18a may update the condition learning results from the held condition learning results to the additional condition learning results aclr. After updating the condition learning results, the unknownness degree calculation unit 18a may calculate the degree of unknownness un based on the updated condition learning results and the detection condition features dcc output from the condition feature generation unit after the update.

The condition learning determination unit 222 determines to execute the additional condition learning when the degree of unknownness un exceeds the predetermined third threshold. If the degree of unknownness un is less than or equal to the predetermined third threshold, the condition learning determination unit 222 determines not to execute the additional condition learning.

The condition learning determination unit 222 may determine to execute the additional condition learning only when a plurality of degrees of unknownness un exceed a predetermined threshold a predetermined number of times continuously in time series.

The anomaly detection device 1a of the present embodiment may include the additional state learning unit 23 in addition to the components of the anomaly detection device 1 described in the first embodiment. The additional state learning unit 23 includes the state feature storage unit 231, the state learning determination unit 232, the state feature extraction unit 233, and the additional state learning execution unit 234.

The state feature storage unit 231 stores the detection state features dsc. The state learning determination unit 232 determines whether or not to execute the additional state learning based on the degree of unknownness un. The state feature extraction unit 233 extracts the detection state features dsc to be used in the additional state learning from the state feature storage unit 231 when the state learning determination unit 232 determines to execute the additional state learning. The additional state learning execution unit 234 outputs the results of the execution of the additional state learning based on the extracted detection state features dsc as the additional state learning results aslr.

The anomaly detection method of the present embodiment may include an additional state learning step in addition to the steps included in the anomaly detection method described in the first embodiment. The additional state learning step includes a state feature storage step, a state learning determination step, a state feature extraction step, and an additional state learning execution step.

The state feature storage step stores the detection state features dsc. The state learning determination step determines whether or not to execute the additional state learning based on the degree of unknownness un. When the state learning determination step determines to execute the additional state learning, the state feature extraction step extracts the detection state features dsc to be used in the additional state learning from the detection state features dsc stored in the state feature storage step. The additional state learning execution step outputs the results of the execution of the additional state learning based on the extracted detection state features dsc as the additional state learning results aslr.

As described above, the present embodiment can provide the anomaly detection device with less false detection and overlooking when detecting the state of the mechanical apparatus 2 with variable operating conditions. By executing the additional condition learning when necessary, the condition learning results held by the unknownness degree calculation unit 18a can be updated. By executing the additional state learning when necessary, the condition learning results held by the anomaly degree calculation unit 14a may be updated. This allows more accurate anomaly detection when the state of the mechanical apparatus 2 with variable operating conditions is detected. Furthermore, the occurrence of false detection and overlooking can be reduced.

### REFERENCE SIGNS LIST

1, 1a anomaly detection device; 2 mechanical apparatus; 3 control device; 11 state signal generation unit; 12 state feature generation unit; 13 initial state learning unit; 14 anomaly degree calculation unit; 15 condition signal generation unit; 16 condition feature generation unit; 17 initial condition learning unit; 18 unknownness degree calculation unit; 19 anomaly determination unit; 20 motor; 22 additional condition learning unit; 23 additional state learning unit; 201 ball screw; 202 moving part; 203 guide; 204 ball screw shaft; 202 coupling; 203 servomotor shaft; 204 servomotor; 205 encoder; 221 condition feature storage unit; 222 condition learning determination unit; 223 condition feature extraction unit; 224 additional condition learning execution unit; 231 state feature storage unit; 232 state learning determination unit; 233 state feature extraction unit; 234 additional state learning execution unit; 310 current sensor; 311 driver; 301 PLC; 401 PC; 402 PLC display; 403 PC display; cc condition feature; clr condition learning result; cs condition signal; df driving force; jr determination result; oc operating condition; power pw; state quantity sa; state feature sc; state learning result slr; state signal ss.

1. An anomaly detection device comprising:
state signal generation circuitry to generate a state signal by detecting, in time series, a state of a mechanical apparatus driven by a motor to operate;
condition signal generation circuitry to generate a condition signal by detecting, in time series, an operating condition indicating an operating status of the mechanical apparatus and being a command specifying operation of the motor;
state feature generation circuitry to generate state features based on the state signal;
condition feature generation circuitry to generate condition features based on the condition signal;
initial state learning circuitry to output, as initial state learning results, results of learning based on initial learning state features that are the state features at a time of initial state learning;
initial condition learning circuitry to output, as initial condition learning results, results of learning based on initial learning condition features that are the condition features at a time of initial condition learning;
anomaly degree calculation circuitry to obtain the initial state learning results or additional state learning results as state learning results and calculate a degree of anomaly based on the state learning results and detection state features that are the state features at a time of detection; and
unknownness degree calculation circuitry to obtain the initial condition learning results or additional condition learning results as condition learning results and calculate a degree of unknownness based on the condition learning results and detection condition features that are the condition features at the time of the detection,
wherein the unknownness degree calculation circuitry is configured to calculate each degree of unknownness based on the detection condition features generated based on the condition signal at a plurality of time points and the condition learning results.

2. The anomaly detection device according to claim 1, comprising anomaly determination circuitry to detect an anomaly in the mechanical apparatus based on the degree of anomaly and the degree of unknownness.

3. The anomaly detection device according to claim 2, wherein
the anomaly determination circuitry determines that the state of the mechanical apparatus is anomalous when the degree of anomaly is greater than a predetermined first threshold and the degree of unknownness is less than a predetermined second threshold.

4. The anomaly detection device according to claim 1, wherein
the condition feature generation circuitry
generates a plurality of statistics calculated from the condition signal at a plurality of time points as the condition features.

5. The anomaly detection device according to claim 1, wherein
the condition feature generation circuitry
generates frequency characteristics of the condition signal in time series by frequency analysis as the condition features.

6. The anomaly detection device according to claim 1, wherein
the operating condition is a control signal to define a shape of a time response of at least one of a position of the motor, a speed of the motor, an acceleration of the motor, a jerk of the motor, or a driving force of the motor.

7. The anomaly detection device according to claim 1, comprising
additional condition learning circuitry,
the additional condition learning circuitry including
condition feature storage circuitry to store the detection condition features,
condition learning determination circuitry to determine whether or not to execute additional condition learning based on the degree of unknownness,
condition feature extraction circuitry to extract the detection condition features to be used in the additional condition learning from the condition feature storage circuitry when the condition learning determination circuitry determines to execute the additional condition learning, and
additional condition learning execution circuitry to output, as the additional condition learning results, results of execution of the additional condition learning based on the extracted detection condition features.

8. The anomaly detection device according to claim 7, wherein when the additional condition learning execution circuitry outputs the additional condition learning results, the unknownness degree calculation circuitry updates the condition learning results from the held condition learning results to the output additional condition learning results, and after performing update of the condition learning results, the unknownness degree calculation circuitry calculates the degree of unknownness based on the updated condition learning results and the detection condition features output, after the update, from the condition feature generation circuitry.

9. The anomaly detection device according to claim 7, wherein the condition learning determination circuitry determines to execute the additional condition learning when the degree of unknownness exceeds a predetermined third threshold, and determines not to execute the additional condition learning when the degree of unknownness is less than or equal to the predetermined third threshold.

10. The anomaly detection device according to claim 7, wherein the condition learning determination circuitry determines to execute the additional condition learning only when the degree of unknownness exceeds a predetermined threshold a predetermined number of times continuously in time series.

11. The anomaly detection device according to claim 7, comprising
additional state learning circuitry,
the additional state learning circuitry including
state feature storage circuitry to store the detection state features,
state learning determination circuitry to determine whether or not to execute additional state learning based on the degree of unknownness,
state feature extraction circuitry to extract the detection state features to be used in the additional state learning from the state feature storage circuitry when the state learning determination circuitry determines to execute the additional state learning, and
additional state learning execution circuitry to output, as the additional state learning results, results of execution of the additional state learning based on the extracted detection state features.

12. A mechanical system comprising:
a mechanical apparatus;
state signal generation circuitry to generate a state signal by detecting, in time series, a state of the mechanical apparatus driven by a motor to operate;
condition signal generation circuitry to generate a condition signal by detecting, in time series, an operating condition indicating an operating status of the mechanical apparatus and being a command specifying operation of the motor;
state feature generation circuitry to generate state features based on the state signal;
condition feature generation circuitry to generate condition features based on the condition signal;
initial state learning circuitry to output, as initial state learning results, results of learning based on initial learning state features that are the state features at a time of initial state learning;
initial condition learning circuitry to output, as initial condition learning results, results of learning based on initial learning condition features that are the condition features at a time of initial condition learning;
anomaly degree calculation circuitry to obtain the initial state learning results or additional state learning results as state learning results and calculate a degree of anomaly based on the state learning results and detection state features that are the state features at a time of detection; and
unknownness degree calculation circuitry to obtain the initial condition learning results or additional condition learning results as condition learning results and calculate a degree of unknownness based on the condition learning results and detection condition features that are the condition features at the time of the detection,
wherein the unknownness degree calculation circuitry is configured to calculate each degree of unknownness based on the detection condition features generated based on the condition signal at a plurality of time points and the condition learning results.

13. An anomaly detection method comprising:
generating a state signal by detecting, in time series, a state of a mechanical apparatus driven by a motor to operate;
generating a condition signal by detecting, in time series, an operating condition indicating an operating status of the mechanical apparatus and being a command specifying operation of the motor;
generating state features based on the state signal;
generating condition features based on the condition signal;
outputting, as initial state learning results, results of learning based on initial learning state features that are the state features at a time of initial state learning;
outputting, as initial condition learning results, results of learning based on initial learning condition features that are the condition features at a time of initial condition learning;
obtaining the initial state learning results or additional state learning results as state learning results and calculating a degree of anomaly based on the state learning results and detection state features that are the state features at a time of detection; and
obtaining the initial condition learning results or additional condition learning results as condition learning results and calculating a degree of unknownness based on the condition learning results and detection condition features that are the condition features at the time of the detection,
wherein, each of the degree of unknownness is calculated based on the detection condition features generated based on the condition signal at a plurality of time points and the condition learning results.

14. The anomaly detection device according to claim 1, wherein the operation of the motor follows the command by feedback control.
